(19) United States
(12) Patent Application Publication
(10) Pub. No.: US 2023/0112618 A1
(43) Pub. Date: Apr. 13, 2023

(54) TIN-BASED PHOTORESIST COMPOSITION AND METHOD OF MAKING

(71) Applicant: Oregon State University, Corvallis, OR (US)

(72) Inventors: Nizan Kenane, Corvallis, OR (US); Douglas A. Keszler, Corvallis, OR (US)

(73) Assignee: Oregon State University, Corvallis, OR (US)

(21) Appl. No.: 17/802,083

(22) PCT Filed: Feb. 25, 2021
(86) PCT No.: PCT/US2021/019658

§ 371 Date: Aug. 24, 2022

Related U.S. Application Data
(60) Provisional application No. 62/982,599, filed on Feb. 27, 2020.

(51) Int. Cl. G03F 7/004; G03F 7/16

(52) U.S. Cl. CPC G03F 7/0042; G03F 7/168

(57) ABSTRACT

Compositions comprising R_{q}SnOₘ(OH)ₓ(HCO₃)_{y}(CO₃)_{z} are disclosed, where R is (i) C₁—C₁₀ hydrocarbyl or (ii) heteroaliphatic, heteroaryl, or heteroaryl-aliphatic including 1-10 carbon atoms and one or more heteroatoms; q = 0.1-1; x ≤ 4; y ≤ 4; z ≤ 2; m = 2 - q/2 - x/2 - y/2 - z; and (q/2 + x/2 + y/2 + z) ≤ 2 Methods of making a photoresist film comprising [(RSn)₁₂O₁₄(OH)₆](OH)₂ on a substrate also are disclosed. The photoresist film may be irradiated to form R_{q}SnOₘ(OH)ₓ(HCO₃)_{y}(CO₃)_{z}.

### CROSS-REFERENCE TO RELATED APPLICATION

This application claims the benefit of the earlier filing date of U.S. Provisional Application No. 62/982,599, filed Feb. 27, 2020, which is incorporated by reference in its entirety herein.

### ACKNOWLEDGMENT OF GOVERNMENT SUPPORT

This invention was made with government support under CHE-1606982 awarded by the National Science Foundation. The government has certain rights in the invention.

### FIELD

This disclosure concerns a tin-based photoresist composition, as well as a method of making and patterning the composition.

### SUMMARY

This disclosure concerns a tin-based photoresist composition, as well as a method of making and patterning the composition. In one embodiment, a tin-based composition comprises R_{q}SnOₘ(OH)ₓ(HCO₃)_{y}(CO₃)_{z} where R is (i) C₁—C₁₀ hydrocarbyl or (ii) heteroaliphatic, heteroaryl, or heteroaryl-aliphatic including 1-10 carbon atoms and one or more heteroatoms; q = 0.1-1; x ≤ 4; y ≤ 4; z ≤ 2; m = 2 - q/2 - x/2 - y/2 - z; and (q/2 + x/2 + y/2 + z) ≤ 2. In another embodiment, a tin-based composition comprises R_{q}SnOₘ(OH)ₓ(HCO₃)_{y}(CO₃)_{z} where R is (i) C₁—C₁₀ hydrocarbyl or (ii) heteroaliphatic, heteroaryl, or heteroaryl-aliphatic including 1-10 carbon atoms and one or more heteroatoms; q = 0.1-1; x ≤ 3.9; y ≤ 3.9; z ≤ 1.95; m = 2 - q/2 - x/2 - y/2 - z; and (q/2 + x/2 + y/2 + z) ≤ 2. In certain embodiments, R is C₁—C₁₀ aliphatic, such as C₁—C₅ alkyl. In some examples, R is n-butyl. In any of the foregoing or following embodiments, x, y, and z may have the following values: (i) 0 < x ≤ 3; or (ii) 0 < y ≤ 3; or (iii) 0 < z ≤ 1.5; or (iv) any combination of (i), (ii), and (iii).

A component may include a substrate and a film on at least a portion of the substrate, the film comprising a tin-based composition as disclosed herein. The film may be patterned on the substrate. In some embodiments, (i) the film has an average thickness within a range of 2-1000 nm; or (ii) the film has a root-mean-square surface roughness < 1.5 nm; or (iii) both (i) and (ii).

In some embodiments, a method of making a tin-based photoresist composition includes exposing RSnX₃ to air, thereby producing [RSnOH(H₂O)X₂]₂, where X is halo and R is as previously defined; preparing a solution comprising the [RSnOH(H₂O)X₂]₂ and a solvent; depositing the solution onto a substrate; heating the deposited solution and the substrate to produce a film comprising [(RSn)₁₂O₁₄(OH)₆]X₂ on the substrate; and contacting the film comprising [(RSn)₁₂O₁₄(OH)₆]X₂ with aqueous ammonia to produce a film comprising [(RSn)₁₂O₁₄(OH)₆](OH)₂ on the substrate. Heating the deposited solution and the substrate to produce a film comprising [(RSn)₁₂O₁₄(OH)₆]X₂ on the substrate may include heating at a temperature within a range of 60-100° C. for 1-5 minutes.

In any of the foregoing or following embodiments, R may be C₁-C₁₀ aliphatic, such as C₁—C₅ alkyl. In some implementations, R is n-butyl. In any of the foregoing or following embodiments, heating the deposited solution and the substrate to produce a film comprising [(RSn)₁₂O₁₄(OH)₆]X₂ on the substrate may comprise heating at a temperature within a range of 60-100° C. for 1-5 minutes.

In any of the foregoing or following embodiments, the method may further include irradiating at least a portion of the film comprising [(RSn)₁₂O₁₄(OH)₆](OH)₂ with an electron beam or light having a wavelength within a range of from 10 nm to less than 400 nm to produce an irradiated film. In some embodiments, irradiating comprises irradiating with light having a wavelength within a range of 10-260 nm, or irradiating with an electron beam at a dose of ≥ 125 µC/cm². In some implementations, irradiating comprises irradiating with an electron beam at a dose of 125-1000 µC/cm². In any of the foregoing embodiments, irradiating may cleave from 10-100% of R—Sn bonds in irradiated portions of the film comprising [(RSn)₁₂O₁₄(OH)₆](OH)₂.

In any of the foregoing or following embodiments, the method may further include a post-irradiation treatment. In some embodiments, the method further comprises (i) exposing the irradiated film to air at ambient temperature for at least 3 hours, or (ii) heating the irradiated film at a temperature within a range of 100-200° C. in air for 2-5 minutes, whereby irradiated portions of the irradiated film adsorb CO₂ from the air, forming R_{q}SnOₘ(OH)ₓ(HCO₃)_{y}(CO₃)_{z}, wherein q = 0.1-1, x ≤ 4, y ≤ 4, z ≤ 2, m = 2 - q/2 - x/2 - y/2 - z, and (q/2 + x/2 + y/2 + z) ≤ 2. In one embodiment, q = 0.1-1, x ≤ 3.9,y ≤ 3.9, z ≤ 1.95, m = 2 - q/2 - x/2 - y/2 - z, and (q/2 + x/2 + y/2 + z) ≤ 2.

In some embodiments, portions of the film comprising [(RSn)₁₂O₁₄(OH)₆](OH)₂ are irradiated to form a patterned film, and the method further includes contacting the patterned film with a solvent in which [(RSn)₁₂O₁₄(OH)₆](OH)₂ is soluble and irradiated portions of the film are less soluble for a period of time effective to dissolve [(RSn)₁₂O₁₄(OH)₆](OH)₂ without dissolving irradiated portions of the patterned film.

Components comprising a substrate and a film on at least a portion of the substrate, the film made by a method as disclosed herein are also encompassed by this disclosure. In one embodiment, the film comprises [(RSn)₁₂O₁₄(OH)₆](OH)₂. In some implementations, (i) the film has a root-mean-square surface roughness of ≤ 0.8 nm, such as a root-mean-square surface roughness ≤ 0.5 nm, or (ii) the film has an undetectable level of Cl⁻ as determined by X-ray photoelectron spectroscopy, or (iii) both (i) and (ii). In an independent embodiment, the film comprises R_{q}SnOₘ(OH)ₓ(HCO₃)_{y}(CO₃)_{z}, wherein q = 0.1-1, x ≤ 4, y ≤ 4, z ≤ 2, m = 2 - q/2 - x/2 - y/2 - z, and (q/2 + x/2 + y/2 + z) ≤ 2. In another independent embodiment, the film comprises R_{q}SnOₘ(OH)ₓ(HCO₃)_{y(}CO₃)_{z}, wherein q = 0.1-1, x ≤ 3.9, y ≤ 3.9, z ≤ 1.95, m = 2 - q/2 - x/2 - y/2 - z, and (q/2 + x/2 + y/2 + z) ≤ 2.

The foregoing and other objects, features, and advantages of the invention will become more apparent from the following detailed description, which proceeds with reference to the accompanying figures.

### BRIEF DESCRIPTION OF THE FIGURES

FIG. 1 is a ball and stick representation of (C₄H₉Sn)₂(OH)₂Cl₄(H₂O)₂ (Sn₂), and ¹H and ¹¹⁹Sn NMR spectra showing that the structure is preserved in 2-heptanone.

FIGS. 2A and 2B are a ball and stick representation of [(n—C₄H₉Sn)₁₂O₁₄(OH)₆](OH)₂ (Sn₁₂OH) (2A) and small angle x-ray scattering data showing that Sn₂ converted to Sn₁₂OH.

FIG. 3 shows XPS spectra of Sn₂ films before and after a base soak.

FIGS. 4A and 4B are atomic force microscopy (AFM) images showing that the deposition of Sn₁₂ from the Sn₂ precursor produces a much smoother film than direct deposition from an Sn₁₂ precursor.

FIGS. 5A and 5B show temperature-programmed desorption/mass spectrometry (TPD-MS) spectra of Sn₂ and Sn₁₂OH films, respectively.

FIG. 6 shows ESI-MS electrospray ionization-mass spectrometry spectra of the films of FIGS. 4A-4B.

FIG. 7 is a graph showing surface roughness of Sn₂ films baked at selected temperatures after base soak.

FIG. 8 shows TPD-MS spectra of Sn₂ films immediately after post-application bake and NH₃(aq) treatment.

FIGS. 9A and 9B are TPD-MS spectra tracking low-temperature H₂O (8A) and CO₂ (8B) desorption with respect to film age.

FIGS. 10A and 10B are TPD-MS spectra showing low-temperature H₂O (9A) and CO₂ (9B) desorption peaks are largely removed with a 140° C., 3 minute bake.

FIG. 11 is a TPD-MS spectrum showing main fragments of 1-butene.

FIG. 12 is a TPD-MS spectrum showing main fragments of butane.

FIG. 13 is a depiction of n-butyl ligand decomposition followed by electron-impact ionization of the possible decomposition products.

FIG. 14 shows TPD-MS spectrum signals associated with n-butyl desorption from samples exposed to 0, 300, and 1000 µC/cm².

FIG. 15 is a graph showing the loss curve for TPD-MS spectrum signals associated with n-butyl desorption from samples exposed to 0, 300, and 1000 µC/cm².

FIG. 16 is a graph showing film thickness as a function of irradiation dose.

FIG. 17 is a scanning electron microscopy image of 25-nm lines written on a 100-nm pitch using an electron beam dose of 500 µC/cm².

FIG. 18 is a reverse-contrast, cross-section cryo-STEM image of an exposed, undeveloped sample.

FIG. 19 is a cryo-EELS spectrum of the sample of FIG. 17 at 10-nm resolution.

FIG. 20 is a graph showing film thickness as function of irradiation dose for arrays aged at 0.25, 3, 24, and 144 hours.

FIG. 21 shows images of dose arrays subjected to 2-hour delays in vacuum (left) and air (right), followed by development in acetone for 30 s.

FIGS. 22A-22C are TPD-MS spectra of unexposed and 1000 µC/cm²-exposed samples tracking n-butyl (22A), water (22B), and carbon dioxide (22C) desorption with no delay time in air.

FIGS. 23A-23C are TPD-MS spectra of H₂O (23A), CO₂ (23B), and n-butyl (23C) desorption from films exposed to 1000 µC/cm² before and after a 10-day delay in air.

FIG. 24 is TPD-MS spectra of butyl fragments after exposure to 1000 µC/cm² after a 10-day delay in air.

FIGS. 25A-25C are TPD-MS spectra of n-butyl (25A), water (25B), and carbon dioxide (25C) desorption from films exposed to 300 µC/cm² after a 1-day delay in air.

FIGS. 26A-26C are TPD-MS spectra of n-butyl (26A), water (26B), and carbon dioxide (26C) desorption from films exposed to 500 µC/cm² after a 6-day delay in air.

FIGS. 27A-27C show that n-butyl groups may be eliminated by heating Sn₁₂ films in air (27A), and the n-butyl deficient films then absorb H₂O (27B) and CO₂ (27C) .

FIG. 28 is TPD-MS spectra of m/z = 41 (n-butyl) of an unexposed film, a film exposed to 10 min of UV light, and a film exposed to 10 min of UV light and delayed in air for 6 days.

FIG. 29 is TPD-MS spectra of m/z = 18 (H₂O) of a film exposed to 10 min of UV light and a film exposed to 10 min of UV light and delayed in air for 6 days.

FIG. 30 is TPD-MS spectra of m/z = 44 (CO₂) of a film exposed to 10 min of UV light and a film exposed to 10 min of UV light and delayed in air for 6 days.

FIG. 31 is TPD-MS spectra of a film exposed to 10 min of UV light and delayed in air for 6 days showing CO₂ fragmentation and an undetected butyl signal.

FIG. 32 depicts chemical reactions for inducing dissolution changes between exposed and unexposed regions of Sn₁₂OH films.

FIG. 33 is a graph showing that both H₂O and CO₂ are required to realize dissolution contrast in an Sn₁₂ film exposed to an electron beam.

FIGS. 34A and 34B are TPD-MS spectra of n-butyl (34A) and water (34B) desorption from films after irradiation at 1000 µC/cm² and after 3 min post-exposure bake (PEB) at 140° C. and 180° C.

FIG. 35 shows thickness measurements for dose arrays subjected to no PEB, 100° C. PEB, 140° C. PEB, and 180° C. PEB for 3 min.

FIG. 36 is TPD-MS spectra showing that heating induces desorption of n-butyl groups from the Sn₁₂ film at lower temperatures.

FIG. 37 is TPD-MS spectra showing CO₂ desorption from the three dose arrays of FIG. 32 after exposure to 1000 µC/cm² and 3 min PEB at 140° C. and 180° C.

FIGS. 38A and 38B are TPD-MS spectra showing n-butyl (38A) and CO₂ (38B) desorption following a 3 min PEB at 320° C. immediately or after a 6-day delay.

FIG. 39 is a table of TPD-MS spectra of unexposed versus exposed samples that were not baked, or were baked at 140° C. or 180° C.

FIGS. 40A and 40B are TPD-MS spectra unexposed (40A) versus exposed (40B) samples following a PEB showing that hydrolyzed Sn is the cite of CO₂ reactivity.

FIGS. 41A-41C are TPD-MS spectra of n-butyl (41A), water (41B), and carbon dioxide (41C) desorption following a PEB at 180° C. with or without a delay.

FIGS. 42A and 42B are TPD-MS spectra following TGA of Sn₁₂OH in N₂ (42A) and Sn₁₂OH baked in air (42B).

FIG. 43 is an SEM image of 10-nm (horizontal) and 14-nm (vertical) lines on a 60-nm pitch produced by Sn₂ deposition, conversion to Sn₁₂OH, electron-beam exposure, post-exposure bake at 140° C., and development in 2-heptanone.

FIG. 44 is an SEM image of line and space patterns and dot patterns produced by Sn₂ deposition, conversion to Sn₁₂OH via an NH3(aq) soak, electron-beam exposure, post-exposure bake at 180° C., and development in 2-heptanone.

### DETAILED DESCRIPTION

Embodiments of a tin-based photoresist composition are disclosed. Methods of making and patterning the composition are also disclosed.

### I. Definitions and Abbreviations

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims.

The disclosure of numerical ranges should be understood as referring to each discrete point within the range, inclusive of endpoints, unless otherwise noted. Unless otherwise indicated, all numbers expressing quantities of components, molecular weights, percentages, temperatures, times, and so forth, as used in the specification or claims are to be understood as being modified by the term “about.” Accordingly, unless otherwise implicitly or explicitly indicated, or unless the context is properly understood by a person of ordinary skill in the art to have a more definitive construction, the numerical parameters set forth are approximations that may depend on the desired properties sought and/or limits of detection under standard test conditions/methods as known to those of ordinary skill in the art. When directly and explicitly distinguishing embodiments from discussed prior art, the embodiment numbers are not approximatations unless the word “about” is recited.

Although there are alternatives for various components, parameters, operating conditions, etc. set forth herein, that does not mean that those alternatives are necessarily equivalent and/or perform equally well. Nor does it mean that the alternatives are listed in a preferred order unless stated otherwise.

Definitions of common terms in chemistry may be found in Richard J. Lewis, Sr. (ed.), Hawley’s Condensed Chemical Dictionary, published by John Wiley & Sons, Inc., 2016 (ISBN 978-1-118-13515-0). The presently disclosed compounds also include all isotopes of atoms present in the compounds, which can include, but are not limited to, deuterium, tritium, ¹⁴C, etc.

In order to facilitate review of the various embodiments of the disclosure, the following explanations of specific terms are provided:
Adsorption: The physical adherence or bonding of ions and molecules onto the surface of another molecule. Adsorption can be characterized as chemisorption or physisorption, depending on the character and strength of the bond between the adsorbate and the surface.
Aliphatic: A substantially hydrocarbon-based compound, or a radical thereof (e.g., C₆H₁₃, for a hexane radical), including alkanes, alkenes, alkynes, including cyclic versions thereof, and further including straight- and branched-chain arrangements, and all stereo and position isomers as well.
Alkyl: A hydrocarbon group having a saturated carbon chain. The chain may be cyclic, branched or unbranched. Examples, without limitation, of alkyl groups include methyl, ethyl, propyl, butyl, pentyl, hexyl, heptyl, octyl, nonyl and decyl. The terms alkenyl and alkynyl refer to hydrocarbon groups having carbon chains containing one or more double or triple bonds, respectively.
Aromatic or aryl: Unsaturated, cyclic hydrocarbons having alternate single and double bonds. Benzene, a 6-carbon ring containing three double bonds, is a typical aromatic compound. If any aromatic ring portion contains a heteroatom, the group is a heteroaryl and not an aryl. Aryl groups are monocyclic, bicyclic, tricyclic or tetracyclic.
Aryl-aliphatic: A group comprising an aromatic portion and an aliphatic portion, wherein the point of attachment to the remainder of the molecule is through the aliphatic portion.
Coating: A layer of material on a surface of a substrate. Synonymous with the term “film”.
Film: A layer of material on a surface of a substrate. Synonymous with the term “coating”.
Halo and Halide: As used herein, the terms “halo” and “halide” refer to Cl, Br, or I.
Heteroaliphatic: An aliphatic compound or group having at least one carbon atom in the chain and at least one heteroatom, i.e., one or more carbon atoms has been replaced with an atom having at least one lone pair of electrons, typically nitrogen, oxygen, phosphorus, silicon, or sulfur. Heteroaliphatic compounds or groups may be substituted or unsubstituted, branched or unbranched, cyclic or acyclic, and include “heterocycle”, “heterocyclyl”, “heterocycloaliphatic”, or “heterocyclic” groups.
Heteroaryl: An aromatic compound or group having at least one heteroatom, i.e., one or more carbon atoms in the ring has been replaced with an atom having at least one lone pair of electrons, typically nitrogen, oxygen, phosphorus, silicon, or sulfur.
Heteroaryl-aliphatic: A group comprising an aromatic portion and an aliphatic portion, wherein the point of attachment to the remainder of the molecule is through the aliphatic portion, the group including at least one heteroatom. Unless otherwise specified, the heteroatom may be in the aromatic portion or the aliphatic portion.
Hydrocarbyl: A univalent radical derived from a hydrocarbon. The hydrocarbyl radical may be linear, branched or cyclic, and may be aliphatic, aryl, or aryl-aliphatic.
Soluble: Capable of becoming molecularly or ionically dispersed in a solvent to form a homogeneous solution.
Solution: A homogeneous mixture composed of two or more substances. A solute (minor component) is dissolved in a solvent (major component).
Sn₂: (C₄H₉Sn)₂(OH)₂Cl₄(H₂O)₂
Sn₁₂OH (or Sn₁₂): (n-C₄H₉Sn)₁₂O₁₄(OH)₈

### II. Photoresist Composition

This disclosure concerns embodiments of a photoresist composition and a method for making the photoresist composition. In one embodiment, the photoresist composition comprises R_{q}SnOₘ(OH)ₓ(HCO₃)y(CO₃)_{z}, where R is (i) C₁—C₁₀ hydrocarbyl or (ii) heteroaliphatic, heteroaryl, or heteroaryl-aliphatic including 1-10 carbon atoms and one or more heteroatoms; q = 0.1-1, x ≤ 4, y ≤ 4, z ≤ 2, m = 2 - q/2 - x/2 - y/2 - z, and (q/2 + x/2 + y/2 + z) ≤ 2. In another embodiment, the photoresist composition comprises R_{q}SnOₘ(OH)ₓ(HCO₃)y(CO₃)_{z} where R is (i) C₁-C₁₀ hydrocarbyl or (ii) heteroaliphatic, heteroaryl, or heteroaryl-aliphatic including 1-10 carbon atoms and one or more heteroatoms; q = 0.1-1, x ≤ 3.9, y ≤ 3.9, z ≤ 1.95, m = 2 - q/2 - x/2 - y/2 - z, and (q/2 + x/2 + y/2 + z) ≤ 2.

In some embodiments, R is C₁—C₁₀ aliphatic, aryl, or aryl-aliphatic wherein the aliphatic portion is the point of attachment to the Sn atom. In certain embodiments, R is C₁—C₁₀ aliphatic, such as C₁—C₅ aliphatic. The aliphatic chain may be linear, branched or cyclic. In some examples, R is C₁—C₅ alkyl. Exemplary R groups include, but are not limited to, methyl, ethyl, n-propyl, isopropyl, n-butyl, iso-butyl (2-methylpropyl), sec-butyl (butan-2-yl), tert-butyl, n-pentyl, 1,1-methylpropyl, 2,2-dimethylpropyl, 1,2-dimethylpropyl, 1-methylbutyl, 2-methylbutyl, 3-methylbutyl, and 1-ethylpropyl. In some embodiments, R is heteroaliphatic, heteroaryl, or heteroaryl-aliphatic (wherein the heteroatom(s) may be in the aryl and/or aliphatic portions, and the aliphatic portion is the point of attachment to the Sn atom) including 1-10 carbon atoms and one or more heteroatoms. Suitable heteroatoms may include N, O, S, and combinations thereof. A heteroaliphatic chain may be linear, branched, or cyclic. In certain examples, R is n-butyl.

In any of the foregoing or following embodiments, q = 0.1-1. In some embodiments, q = 0.3-1 or 0.5-1. In any of the foregoing or following embodiments, x ≤ 4. In one embodiment, x ≤ 3.9. In some embodiments, 0 < x ≤ 4, 0 < x ≤ 3.9, or 0 < x ≤ 3. In any of the foregoing or following embodiments, y ≤ 4. In one embodiment, y ≤ 3.9. In some embodiments, 0 < y ≤ 4, 0 <y ≤ 3.9, or 0 < y ≤ 3. In any of the foregoing or following embodiments, z ≤ 2. In one embodiment, z ≤ 1.95. In some embodiments, 0 < z ≤ 2, 0 < z ≤ 1.95, or 0 < z ≤ 1.5.

In any of the foregoing or following embodiments, the photoresist composition may be deposited as a film or layer onto a substrate. In some embodiments, the film has an average thickness within a range of 2 nm to 1000 nm and/or a root-mean-square (RMS) surface roughness ≤ 1.5 nm. In certain embodiments, the average thickness is within a range of 2-750 nm, such as 2-500 nm, 2-250 nm, 5-250 nm, 10-100 nm, or 10-50 nm. The RMS surface roughness may be ≤ 1.5 nm, < 1.5 nm, ≤ 1.2 nm, < 1.2 nm, ≤ 1 nm, or < 1 nm, such as within a range of 0.2-1.5 nm, 0.3-1.5 nm, 0.3-1.2 nm, 0.3-1 nm, or 0.3-0.75 nm.

### III. Method for Making and Patterning the Photoresist Composition

A smooth, dense film comprising the photoresist composition is desirable. In some embodiments, superior films are prepared by forming an OH-stabilized butyltin dodecamer in situ on a substrate and subsequently forming the photoresist composition as disclosed herein.

Organotin coatings having a general composition represented by R_{z}SnO_{(2—(x/2)—(x/2)}(OH)ₓ where 0 < (x+z) < 4 have been shown to perform well as radiation patternable materials commonly known as photoresists. The use of organotin materials as photoresists having sensitivity to electron beams, ultraviolet (UV) radiation, and extreme ultraviolet (EUV) radiation has been described in U.S. Pat. No. 9,310,684 B2 by Meyers, entitled “Organometallic Solution Based High Resolution Patterning Compositions,” and in U.S Pat. No. 10,228,618 B2 by Meyers, entitled “Organotin Oxide Hydroxide Patterning Compositions, Precursors, and Patterning,” both of which are incorporated herein by reference.

The present disclosure describes preparation of an organotin precursor described by the formula [RSnOH(H₂O)X₂]₂ which can be prepared by reaction of RSnX₃ with water, where X is a halide and R is as previously defined. In one embodiment, RSnX₃ is exposed to ambient air, thereby producing [RSnOH(H₂O)X₂]₂. [RSnOH(H₂O)X₂]₂ forms spontaneously when RSnX₃ is exposed to air for an effective period of time, such as for 2-4 days. In some embodiments, X is Cl⁻. In certain examples, R is n-butyl.

In general, organotin oxide hydroxide coatings can be prepared by reacting a hydrolytically sensitive organotin precursor composition with water. The foregoing references describe organotin oxide hydroxide coatings prepared by spin coating and vapor deposition techniques. Patternable organotin oxide hydroxide coatings can be formed through dissolution of hydrolysates of one or more RₙSnL_{4—n}(n = 1, 2) compositions in a suitable solvent followed by deposition via spin coating. Furthermore, owing to the relatively high vapor pressures of RₙSnL_{4—n} compositions, organotin oxide hydroxide coatings can also be prepared by a vapor deposition technique wherein hydrolysable vapor phase precursors can be introduced into a reactor closed from the ambient atmosphere and hydrolyzed as part of the deposition process. For example, one or more RₙSnL_{4—n} compositions can be reacted with one or more small molecule gas-phase reagents such as H₂O, H₂O₂, O₃, O₂, CH₃OH, and the like to form organotin oxide hydroxide compositions on a desired substrate. Potential vapor deposition techniques include atomic layer deposition (ALD), physical vapor deposition (PVD), chemical vapor deposition (CVD), and the like.

If solution deposition of the organotin coating is desired, a solution comprising [RSnOH(H₂O)X₂]₂ and a solvent can be prepared. In general, any solvent in which the [RSnOH(H₂O)X₂]₂ composition is soluble may be used. Solvent choice can be further influenced by other parameters, such as its toxicity, flammability, volatility, viscosity, and potential chemical interactions with other materials. Suitable solvents include, for example, alcohols, such as 4-methy-2-pentanol and propylene glycol methyl ether (PGME), ketones, such as 2-heptanone, esters, such as propylene glycol monomethyl ether acetate (PGMEA), and the like, and/or mixtures thereof.

The concentration of the species in solution can be assessed on a Sn molar basis and can generally be selected for desired physical properties of the solution and the desired coating. For example, higher concentration solutions generally result in thicker films and lower concentration solutions generally result in thinner films. In some applications, such as for ultrahigh resolution patterning, thinner films can be desirable. In some embodiments, Sn concentrations can be from 0.005 M to 1.4 M, in further embodiments from 0.02 M to 1.2 M, and in additional embodiments from 0.1 M to 1.0 M. Additional ranges of Sn concentrations within the explicit ranges are contemplated and would be recognized by one of ordinary skill in the art.

If vapor deposition is desired, the formation of [RSnOH(H₂O)X₂]₂ can be effectuated, for example, by gas-phase reaction of RSnX₃ and H₂O in a chamber isolated from the ambient environment. An organotin precursor RSnX₃ can be introduced into the chamber by means known to those of ordinary skill in the art, such as by using a flow of vapor, aerosol, and/or direct liquid injection into the vaporization chamber. Water can then be introduced to the chamber through a separate inlet, either simultaneous with or subsequent to introduction of the organotin precursor, to drive hydrolysis and formation of a [RSnOH(H₂O)X₂]₂ coating on the surface of a substrate. In some embodiments the reaction can take place at an elevated temperature relative to the ambient. In some embodiments, the vapor phase reaction can be conducted multiple times until a desired film thickness is achieved.

For either method of deposition, the substrate may be any material of interest. Exemplary substrates include, but are not limited to silicon, silica, ceramic materials, polymers, and combinations thereof. In some embodiments, the substrate comprises a flat or substantially flat surface on which the solution is deposited. In certain embodiments, the substrate is SiO₂. Solution deposition may be performed by any suitable method including, but not limited to, spin-coating, spray-coating, dip-coating, and the like. The deposited solution and substrate are heated to produce a film comprising [(RSn)₁₂O₁₄(OH)₆]X₂ on the substrate. The temperature and time are selected to effectively evaporate the solvent and convert the [RSnOH(H₂O)X₂]₂ to the dodecameric [(RSn)₁₂O₁₄(OH)₆]X₂. In some embodiments, the substrate and deposited solution are subjected to a post-application bake at a temperature of 60-100° C. for a time of 1-5 minutes, such as a temperature of 80° C. for 3 minutes. In certain embodiments, the [(RSn)₁₂O₁₄(OH)₆]X₂ film has a RMS surface roughness < 0.5 nm or < 0.4 nm. In some examples, the RMS surface roughness is ≈ 0.3 nm. RMS surface roughness can be determined by methods known in the art, such as by atomic force microscopy.

Halides are an undesirable component of tin-based photoresists because the halide may allow uncontrolled hydrolysis and/or chemically and structurally in-homogeneous films. Thus, it is beneficial to remove the halide from the deposited film. In any of the foregoing or following embodiments, the halide may be removed by contacting the film comprising [(RSn)₁₂O₁₄(OH)₆]X₂ with an aqueous base to produce a film comprising [(RSn)₁₂O₁₄(OH)₆](OH)₂ on the substrate. It can be desirable to avoid contamination of the material with other metals, so it is generally desirable for the aqueous base to not contain metals, although the conversion of the halide containing film to a non-halide containing film can otherwise still be achieved. Suitable aqueous bases can include, for example, quaternary ammonium compounds (e.g, tetramethyl ammonium hydroxide, tetrabutyl ammonium hydroxide, and the like), alkylamine compounds (e.g, diethylamine, ethylamine, dimethylamine, methylamine, and the like), and ammonia. In some embodiments, the aqueous base is aqueous ammonia. The halide may be substantially removed from the film by treating it with dilute aqueous ammonia for a short period of time. The ammonia may have a concentration of from 5 µM to 100 mM, such as 5 µM to 50 mM, 5 µM to 10 mM, 5 µM to 1 mM, 5 µM to 100 µM, 5 µM to 50 µM, 5 µM to 10 µM. The short period of time may be from 30 seconds to 30 minutes, such as from 30 seconds to 15 minutes, 1 minute to 10 minutes, or 1 minute to 5 minutes. In some examples, the halide was chloride and was removed by submerging the films in 10 µM NH₃(aq) for 3 minutes after deposition and the post-application bake. Alternatively, NH₃(aq) may be puddled on the film followed by removal of the aqueous solution by spinning the substrate dry on a spin coater. After alkaline treatment, the [(RSn)₁₂O₁₄(OH)₆](OH)₂ film may be rinsed with water and dried. Drying may be performed by flowing nitrogen across the rinsed film and/or by heating. Halide removal may slightly increase the roughness of the film. Thus, in some embodiments, the [(RSn)₁₂O₁₄(OH)₆](OH)₂ film has a RMS surface roughness < 1.5 nm, ≤ 1 nm, or ≤ 0.8 nm, such as a RMS surface roughness within a range of 0.3 nm to 1 nm, 0.3 nm to 0.8 nm or 0.3 nm to 0.5 nm.

In some embodiments, an atomically smooth film (e.g., RMS surface roughness < 0.5 nm) comprising [(RSn)₁₂O₁₄(OH)₆](OH)₂ is formed on a substrate, where R is as defined above. The [(RSn)₁₂O₁₄(OH)₆](OH)₂ film may be formed from a precursor comprising RSnX₃ where X is halide. In some examples, the starting material is n—C₄H₉SnCl₃, and the reactions are as follows;

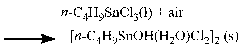

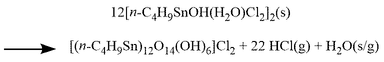

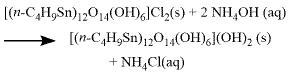

In any of the foregoing or following embodiments, the [(RSn)₁₂O₁₄(OH)₆](OH)₂ film is a photoresist film that may be patterned by irradiation with an electron beam or light having a wavelength within a range of from 10 nm to less than 400 nm, such as 10 nm to 350 nm, 10 nm to 300 nm, 50 nm to 300 nm, 100 nm to 300 nm, 150 nm to 300 nm, or 200 nm to 275 nm, to produce an irradiated film. In some embodiments, irradiating comprises irradiating with light having a wavelength within a range of 10-260 nm, such as with EUV light having a wavelength of 13.5 nm, or with an electron beam at a dose of ≥ 125 µC/cm². In certain embodiments, irradiating comprises irradiating with light having a wavelength within a range of 200-260 nm or 250-260 nm. In other embodiments, irradiating comprises irradiating with an electron beam at a dose of ≥ 125 pC/cm², ≥ 200 pC/cm², ≥ 300 pC/cm², or ≥ 500 pC/cm², such as a dose within a range of 125-1000 pC/cm², 200-1000 pC/cm², 300-1000 pC/cm², or 500-1000 µC/cm². Irradiation cleaves at least a portion of the R—Sn bonds (more particularly, C—Sn bonds) in the [(RSn)₁₂O₁₄(OH)₆](OH)₂ film. In some embodiments, sufficient irradiation is applied to cleave up to 5%, up to 10%, up to 25%, up to 50%, up to 70%, up to 90%, or up to 100% of the R—Sn bonds, such as from 0-100%, 1-100%, 1-90%, 1-70%, or 1-50% of the R—Sn bonds. In other embodiments, sufficient irradiation is applied to cleave 5-100%, 5-90%, 5-70%, 5-50%, 10-100%, 10-90%, 10-70%, or 10-50% of the R—Sn bonds. Cleavage leads to desorption of the R group from the film.

In any of the foregoing or following embodiments, the photoresist film may be patterned by irradiating only selected portions of the [(RSn)₁₂O₁₄(OH)₆](OH)₂ film. In some embodiments, selected portions are irradiated by “writing” with an electron beam or by masking certain portions of the film and irradiating the unmasked portions.

In any of the foregoing embodiments, the method may include a post-irradiation treatment of the film. In some embodiments, the post-irradiation treatment comprises exposing the irradiated film to air at ambient temperature (e.g., 20-25° C.) for at least three hours or heating the irradiated film at a temperature within a range of 100-200° C. in air for 2-5 minutes. In certain embodiments, the post-irradiation treatment comprises heating the irradiated film at a temperature within a range of from 140-180° C. for 2-4 minutes, such as at 140-180° C. for 3 minutes. In other embodiments, the post-irradiation treatment comprises simply exposing the irradiated film to air at ambient temperature for an extended period of time, such as at least 3 hours, at least 5 hours, at least 12 hours, at least 24 hours, at least 2 days, at least 3 days, at least 7 days, or at least 10 days.

Exposure of the film to air during the post-irradiation treatment hydrolyzes exposed irradiated areas of the film, increasing the concentration of Sn—OH bonds in the film. Over time, the film adsorbs CO₂ from the air. Without wishing to be bound by a particular theory of operation, the adsorbed CO₂ inserts into the Sn—OH bond to form Sn—HCO₃ bonds. Adjacent HCO₃⁻ and OH⁻ groups may then react and release H₂O, thereby forming simple carbonates (e.g., a carbonate group shared between two adjacent Sn atoms). In some embodiments, the resulting film has a general formula comprising R_{q}SnOₘ(OH)ₓ(HCO₃)_{y}(CO₃)_{z} where R, m, q, x, y, and z are as previously defined.

The presence of bicarbonate and carbonate groups in the film provides a differential dissolution contrast to the [(RSn)₁₂O₁₄(OH)₆](OH)₂ film and to [(RSn)₁₂O₁₄(OH)₆](OH)₂ films where from 10-100% of the R—Sn bonds have been cleaved. The resulting CO₃²⁻ groups that form bridge adjacent Sn atoms and inhibit solubility via crosslinking. In particular, R_{q}SnOₘ(OH)ₓ(HCO₃)_{y}(CO₃)_{z} is less soluble in certain solvents than [(RSn)₁₂O₁₄(OH)₆](OH)₂. For instance, [(RSn)₁₂O₁₄(OH)₆](OH)₂ readily dissolves in certain ketones (e.g., 2-heptanone, acetone), whereas R_{q}SnOₘ(OH)ₓ(HCO₃)_{y}(CO₃)_{z} is insoluble or less soluble. Thus, in some embodiments, the patterned film is contacted with a solvent in which [(RSn)₁₂O₁₄(OH)₆](OH)₂ is soluble and irradiated portions of the film are less soluble for a period of time effective to dissolve [(RSn)₁₂O₁₄(OH)₆](OH)₂ without dissolving irradiated portions of the patterned film. In some embodiments, the non-irradiated portions of the photoresist layer are removed by contacting the patterned photoresist layer with 2-heptanone for a period of several seconds to several minutes, such as for 15 seconds to 2 minutes, 15 seconds to 1 minute, or 15-45 seconds. In certain examples, the patterned photoresist layer was contacted with 2-heptanone for 30 seconds.

### IV. Components

Components are made by embodiments of the disclosed method. In some embodiments, a component comprises a substrate and a film on at least a portion of the substrate, wherein the film comprises [(RSn)₁₂O₁₄(OH)₆](OH)₂; R is defined as above. The film may have (i) a root-mean-square surface roughness of ≤ 0.8 nm, (ii) an undetectable level of Cl⁻ as determined by X-ray photoelectron spectroscopy, or (iii) both (i) and (ii).

In any of the foregoing or following embodiments, the film may be patterned as disclosed herein to provide a patterned component comprising the substrate and a film on at least a portion of the substrate, the film comprising R_{q}SnOₘ(OH)ₓ(HCO₃)_{y}(CO₃)_{z}, wherein q, x, y, z; and m are as previously defined.

In any of the foregoing embodiments, the substrate may be any material of interest. Exemplary substrates include, but are not limited to silicon, silica, ceramic materials, polymers, and combinations thereof. In some embodiments, the substrate comprises a flat or substantially flat surface on at least a portion of which the film is disposed. In certain embodiments, the substrate is SiO₂.

### V. Examples

Materials. (C₄H₉Sn)₂(OH)₂Cl₄(H₂O)₂ (Sn₂) crystals were prepared placing by n-C₄H₉SnCl₃(l) (Alfa Aesar, 96%) in a crystallization dish in a fume hood and allowing 3 days for Sn₂ to crystallize, as described previously by Luijten (Recueil des Travaux Chimiques des Pays-Bas 1966, 85(9):873-878). (n-C₄H₉Sn)₁₂O₁₄(OH)₈ (Sn₁₂OH) crystals were prepared as described previously by Eychenne-Baron et al. (.J Organometallic Chem 1998, 567(1): 137-142).

Thin-film coating. Solution-deposition precursors of Sn₂ and Sn₁₂ were prepared by dissolving 0.14 g and 0.12 g, respectively, of each per 1 mL of 2-heptanone (Alfa Aesar, 99%), respectively, and filtering with 0.45 µm PTFE syringe filters. The 100 nm thermally-grown SiO₂ on p-Si (Silicon Valley Microelectronics, Inc) substrates were washed with acetone, isopropyl alcohol, and 18.2 MQ-cm H₂O, and annealed at 800° C. for 15 min. Precursor solutions were spun on 2.54 x 2.54 cm² at 2000 RPM for 30 s. Samples were immediately transferred to a preheated hot plate at 80° C. for a post-application bake for 3 min.

Thin films prepared from Sn₂ were subjected to an alkaline treatment. These films were fully submerged in 10 µM NH₃(aq) for 3 min immediately after deposition and 80° C. PAB. After the alkaline treatment, films were rinsed with 18.2 MΩ·cm H₂O and dried off with N₂ gun.

Exposure and contrast curves. Sn₁₂OH films prepared from Sn₂ were used for patterning experiments. Electron beam exposures were performed using a 30-kV electron beam on a Quanta 3D Dual Beam SEM and NPGS software. Contrast curves were prepared by writing an array of squares at linearly increasing doses. Post-exposure aging in air or baking steps were applied as specified in the text. We developed the dose arrays by covering them in a few drops of 2-heptanone for 30 s, and then dried the samples with a N₂ gun. Thickness measurements were collected at each square using a Woolam MX-2000 ellipsometer with focus probes attached. Thickness values were plotted as a function of dose or log dose. Exposure to UV light was done using Digital UV Ozone System (Novascan) emitting two wavelengths at λ = 254 and 185 nm.

XPS. A Physical Electronics (PHI) 5600 MultiTechnique UHV system was used for collection of X-ray photoelectron spectroscopy (XPS). The base pressure of the main chamber was < 2 × 10⁻¹⁰ torr. Monochromatized Al Kα radiation (hv = 1486.6 eV, 300 W, 15 kV) was used to obtain Ag 3d, Cl 2p, Sn 3d, and Sn MNN Auger spectra. An electron analyzer pass energy of 23.5 eV, and a 45 ° emission angle were used for the measurements. Peak fits for each spectra were determined using Casa XPS using Gaussian-Lorentzian line shapes and a Shirley background (Frisch et al., Gaussian 16, Revision A.03, 2016). Atomic concentrations were calculated using published sensitivity factors specific to the XPS system used for a 90 ° between the X-ray source and electron detector (Perdew et al., Phys. Rev. Lett. 1997, 78(7):1396).

AFM. Atomic force microscopy was performed to measure RMS roughness values using Bruker Veeco Innova SPC in tapping mode. Nanoscope Analysis 1.5 was used for leveling background subtraction and noise.

TPD. TPD-MS was performed using a Hiden Analytical TPD Workstation. Films were cleaved into 1 × 1 cm² samples and inserted into the UHV chamber of the instrument (~3 × 10⁻⁹ torr). Samples were annealed to 800° C. at a linear ramp rate of 30° C./min. MS were acquired with a 70-eV electron-ionization energy and 20-µA emission current. Select mass-to-charge (m/z) ratios for each sample were monitored in MID mode with dwell and settle times of 150 and 50 ms, respectively.

SEM. Scanning electron microscopy images were collected using a 30-kV electron beam on a Quanta 3D Dual Beam SEM.

ESI-MS. Extracted-film solutions were analyzed with an Agilent 6230 electrospray ionization mass spectrometer. Solutions were introduced into the spectrometer at a flow rate of 0.4 mL/min using a syringe pump. N₂(g) at 325° C. and 241 kPa was flowed at 8 L/min to assist with solution vaporization. The voltage of the capillary was set at 3500 V, the skimmer was set at 65 V and the RF octopole was set at 750 V. The data were collected in both positive and negative ionization modes with the fragmentation voltage set to 30 V.

TEM and EELS. TEM images were collected using a 200 keV beam on a FEI Titan 80-200 TEM. EELS analyses were performed on the Titan using a Gatan Tridiem energy analyzer with convergence angle, and collection angle of 10 milli radian. The Gatan 626, single tilt cryo holder used for TEM and EELS remained steady at -170° C. throughout the experiments. With one tilt axis, the sample was brought very close to the Si <110> zone axis ensuring the sample was perpendicular to the beam.

### Results and Discussion

### Atomically Smooth, Cl-Free, Thin Films From Sn₂

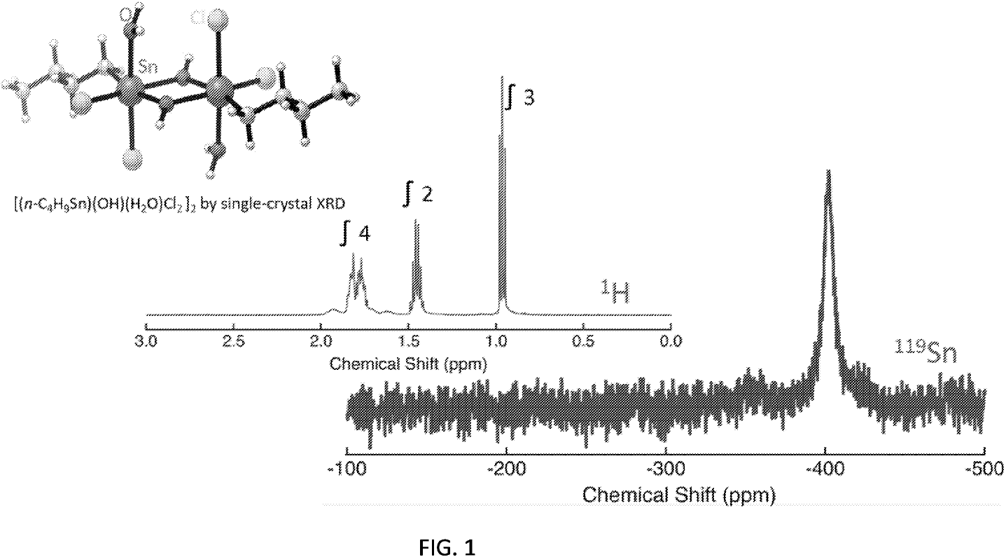

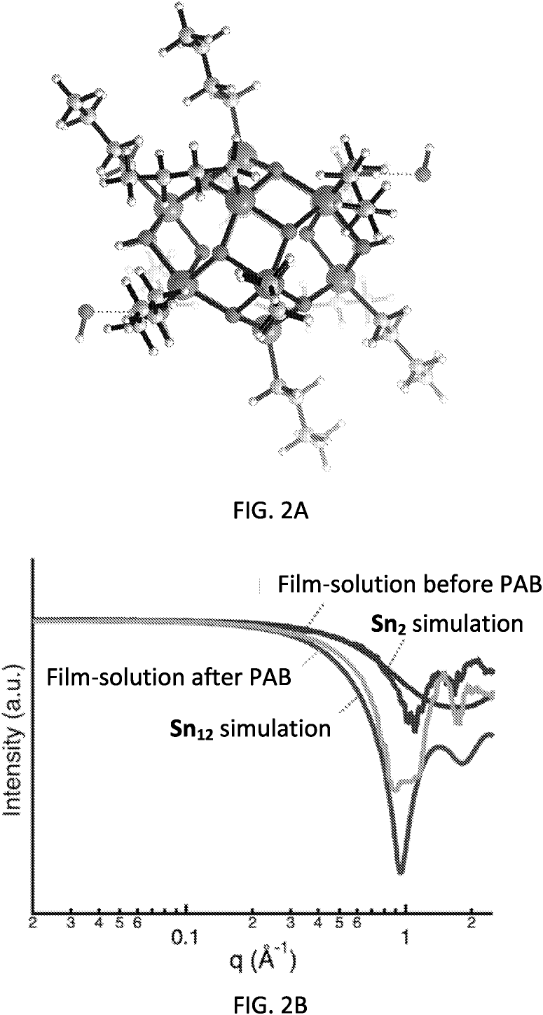

Sn₂ possesses 4 Cl ligands (FIG. 1). The two Sn atoms share hydroxyl groups. Two Cl ligands and one H₂O molecule are associated with each Sn atom. An n-butyl group is also bound to each Sn atom. A Sn₂ solution precursor converts to the chloride salt of the butyltin dodecamer -[(n—C₄H₉Sn)₁₂O₁₄(OH)₆]Cl₂ (Sn₁₂Cl) — after deposition by spin coating and a post-application bake (PAB) at 80° C. The films are ultra-smooth with root-mean-square (RMS) roughness = 0.3 nm. Chloride is an undesirable component of tin-based photoresists, as it creates opportunities for uncontrolled hydrolysis and production of chemically and structurally inhomogeneous films, which can then affect pattern fidelity during various steps of the patterning process. The chloride salts were converted to Cl-free films by substitution with OH⁻. As OH-stabilized butyltin dodecamers have previously been reported, [(n-C₄H₉Sn)₁₂O₁₄(OH)₆](OH)₂ (Sn₁₂OH, FIGS. 2A and 2B), it was hypothesized that OH⁻ would exchange for Cl⁻ based on the stronger nucleophilic character of OH⁻.

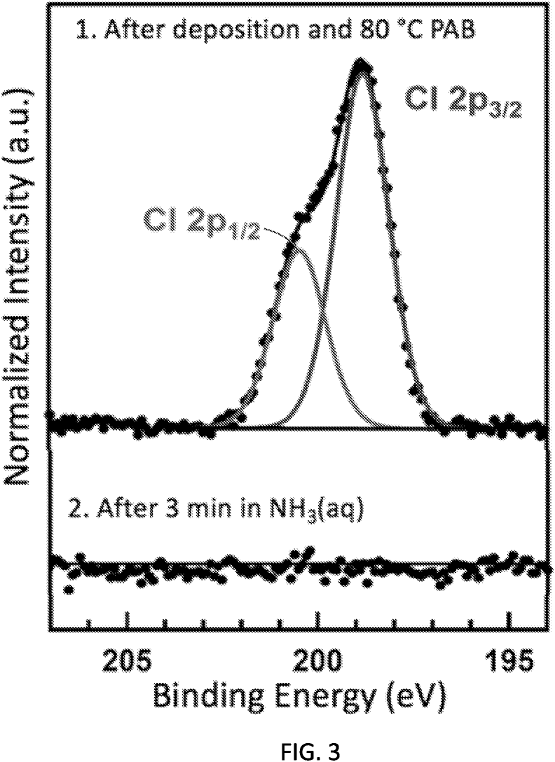

Accordingly, films of Sn₁₂Cl were submerged in 10 µM NH₃(aq) for 3 min immediately after deposition and a soft PAB at 80° C. The X-ray photoelectron spectroscopy (XPS) spectrum at the top of FIG. 3 shows strong Cl 2p_{1/2} and 2p_{3/2} signals in the film after deposition and PAB, prior to the base soak. The bottom spectrum shows that the Cl signal merges into the background after immersing the film in NH₃(aq). This result was interpreted to mean that the 3 min soak in NH₃(aq) removed Cl⁻ from the film and produced the OH⁻ salt of the dodecamer.

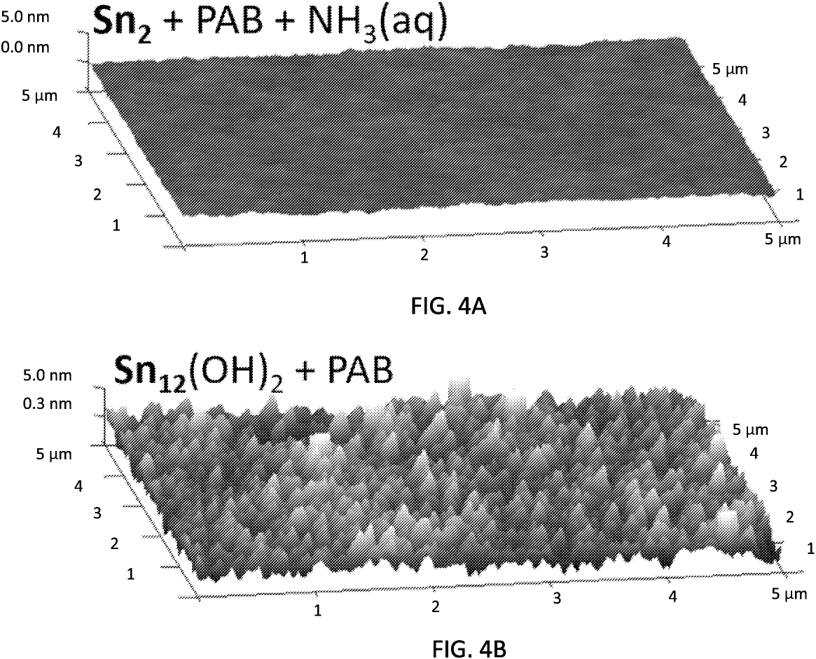

Surface images of films were collected via atomic force microscopy (AFM) after the NH₃(aq) bath (FIGS. 4A and 4B). The RMS roughness of resultant films slightly increased from 0.32 to 0.45 nm, but was still indicative of an atomically smooth surface. The alkaline treatment did not severely degrade the smooth film morphologies of films prepared from Sn₂. As seen in FIG. 4A, deposition of Sn₁₂ from the Sn₂ precursor produces a much smoother film than direct deposition from an Sn₁₂ precursor. Equations 1 and 2 summarize the chemical reactions of Sn₂ from solid-state crystals to atomically-smooth, Cl-free, patternable, n-butyltin oxo hydroxo thin films:

Deposition and PAB:

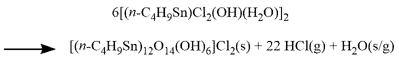

Base soak:

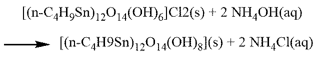

To confirm that films coated from Sn₂ produce on-wafer Sn₁₂OH speciation after the PAB and base soak, bulk crystals of Sn₁₂OH were prepared and then films were deposited from 2-heptanone solutions. Deposition and process parameters for the Sn₂ and Sn₁₂OH solution precursors only differed by the 3-min ion exchange of Sn₂ films (Sn₁₂Cl) in NH₃(aq).

Table 1 summarizes measured chemical compositions from XPS data and computed compositions based on the formula of Sn₁₂OH. The atomic concentrations of Sn, O, C, and Cl of films spun from the Sn₂ matched within 3% for films spun from Sn₁₂OH, and within 2% of the expected composition from the molecular formula.

TABLE 1

XPS At% concentrations of Sn₂- and Sn₁₂OH-prepared films

| | Sn₂ deposition + 80° C. PAB + NH₃(aq) | Sn₁₂OH deposition + 80° C. PAB | Sn₁₂OH molecular formula |
|---|---|---|---|
| Total Sn | 14% | 14% | 15% |
| Total C | 57% | 59% | 59% |
| Total O | 27% | 24% | 27% |
| Total Cl | 0% | 0% | 0% |
| Total Si | 1% | 2% | 0% |
| Total N | 0% | 0% | 0% |
| a′ | 918.1 | 918.2 | |

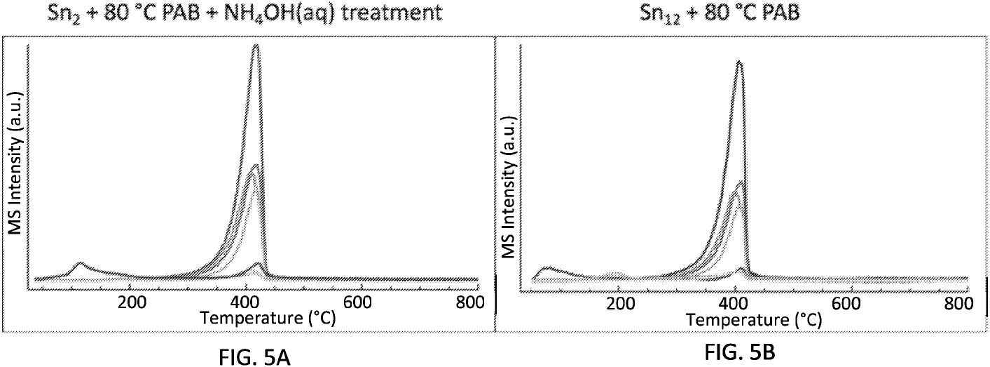

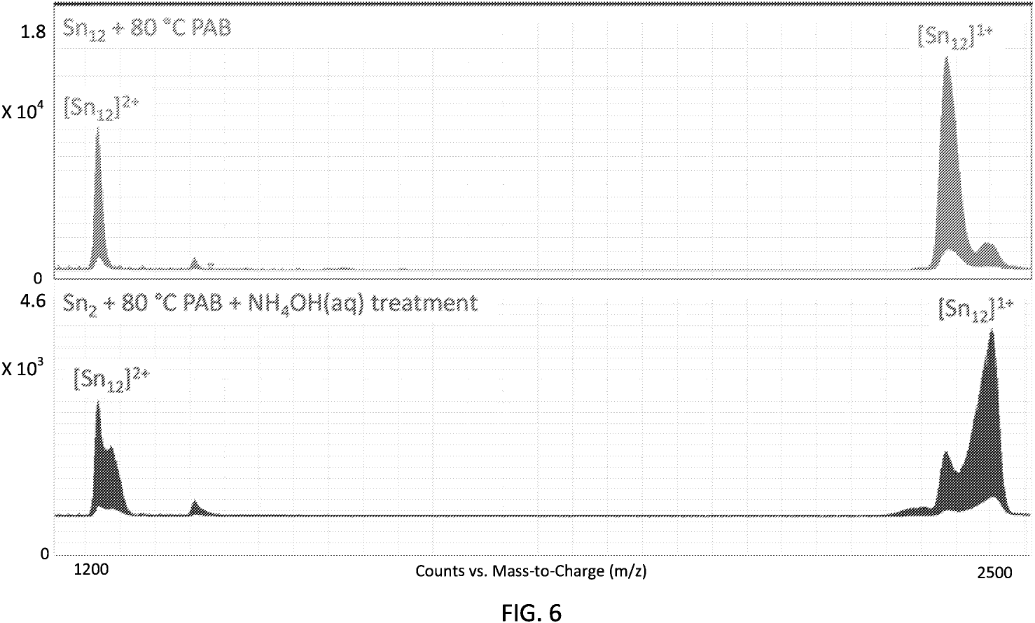

FIGS. 5A and 5B show temperature-programmed desorption (TPD) spectra collected on both films. The desorption masses, peak signal temperatures, and relative peak intensities were indistinguishable between the two films. The films were extracted by immersion and dissolution in methanol, creating solutions from which to assess on-wafer speciation. The electrospray ionization-mass spectrometry (ESI-MS) of the extracted-film solutions were identical (FIG. 6), revealing two dominant peaks centered at ~ 1250 and 2500 mass-to-charge ratios (m/z). These peaks correspond to the +2 and +1 ions of the parent Sn₁₂OH dodecamer. The observed doublets are a result of —OH and —OCH3 ligand exchange within the dodecameric cation.

The ESI-MS spectra of the two samples are differentiated by varying degrees of peak splitting, which occurs because of partial exchange of —OH for —OCH₃ ligands. This exchange can only occur during the dissolution process in methanol, as it is the first and only introduction of a source of methoxo ligands into the system. As such, the distinctive peak splittings do not represent differences in on-wafer speciation.

The XPS, TPD, and ESI-MS provide complementary evidence of on-wafer Sn₁₂OH speciation, regardless of solution-precursor identity. Consequently, they support transformation of Sn₂ to Sn₁₂OH upon deposition, PAB, and base soak.

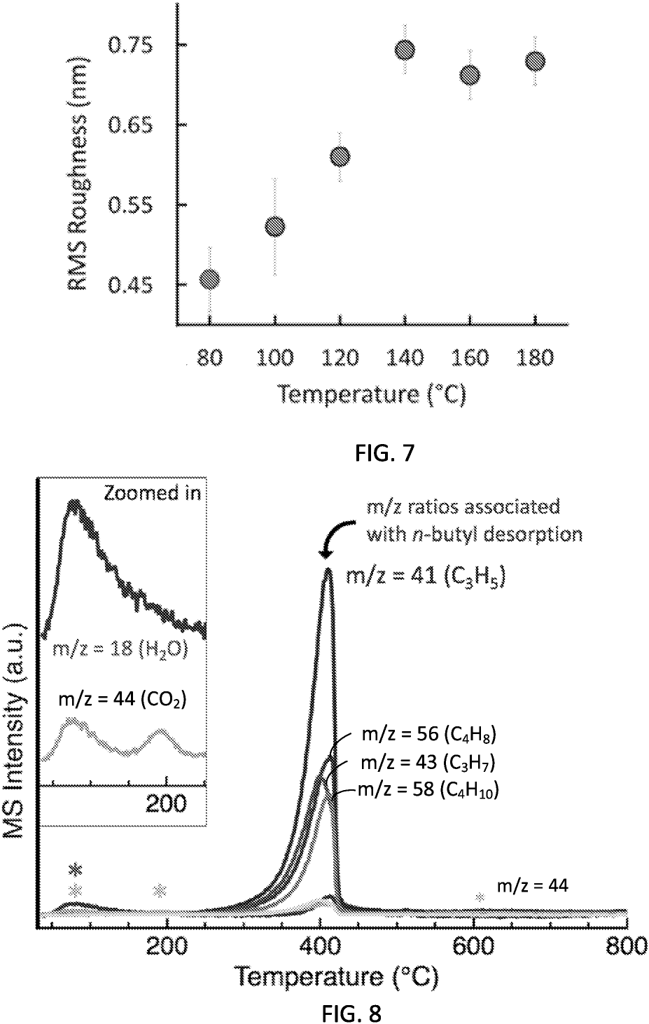

Organotin photoresists are commonly heated after coating and radiation exposure in a lithographic process. These materials must maintain low surface roughness in order to produce high-resolution patterns. Additional 3 min bakes were performed after the NH₃(aq) treatment to assess roughness behavior at elevated temperatures. FIG. 7 shows that despite initial surface roughening, films baked between 140 - 180° C. maintained ~ 0.75 nm RMS roughness. This data suggests that films subjected to typical PAB and PEB processing temperatures will continue to exhibit excellent, sub-0.75 nm roughness, a prerequisite of high-resolution photoresist materials.

Despite identical on-wafer speciation, all radiation experiments were performed on Cl-free films produced from Sn₂. The Sn₂ process produced smoother surfaces (RMS = 0.45 nm) than direct deposition of Sn₁₂OH (RMS = 1.32 nm). Furthermore, when baking films spun directly from Sn₁₂OH, surface morphology quickly roughened to 4.43 nm by 140° C.

### Patterning Chemistries

### Unexposed Films, Establishing a Baseline

TPD-MS was performed to analyze the thermally-induced desorption spectra from Cl-free thin films prepared from Sn₂. The spectrum, shown in FIG. 8, reveals three main desorption signals from H₂O, CO₂, and the n-butyl ligand.

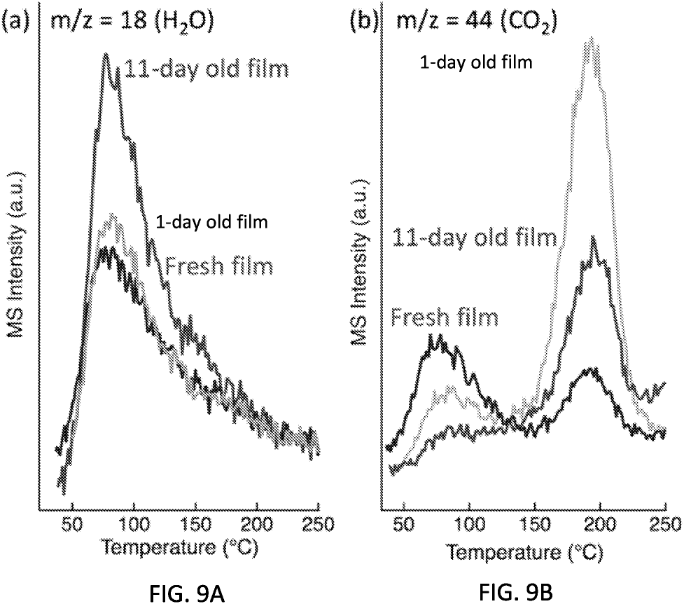

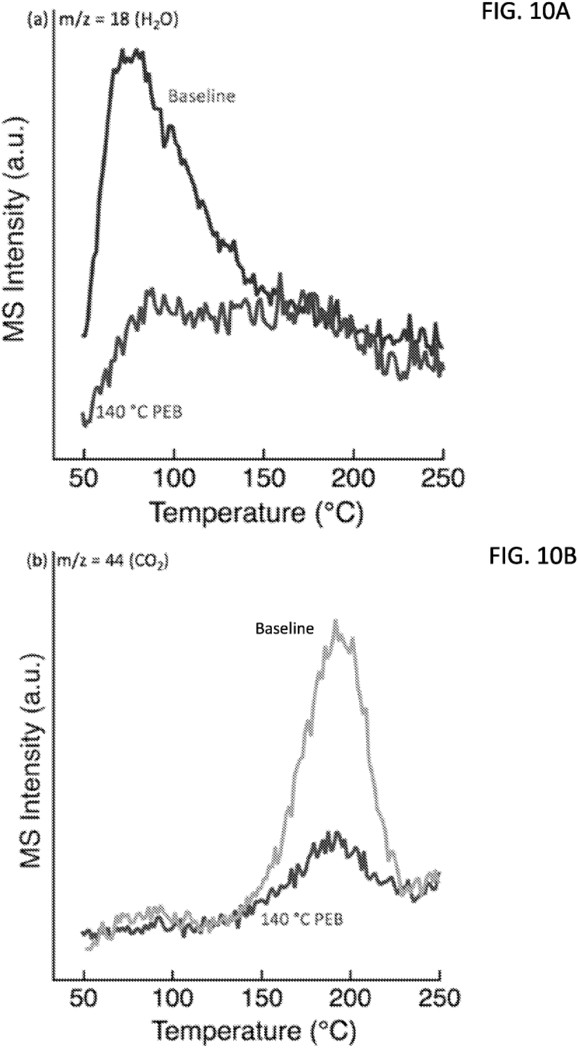

FIG. 8 shows three low-intensity signals at temperatures below 200° C. The water peak at 75° C. is attributed to desorption of constitutional H₂O. This peak grew larger with film aging in air (FIG. 9A) over 11 days, suggesting that the films slowly and continuously adsorbed atmospheric H₂O(g) over this period. The CO₂ peaks at 75 and 200° C. are attributed to desorption of weakly-adsorbed CO₂, as CO₂(g) interactions with metal oxide surfaces is expected. The relative intensities of these two CO₂ desorption peaks changed irregularly over time in air (FIG. 9B). This behavior could be attributed to the dynamic migration of weakly-adsorbed CO₂ on metal oxide surfaces. The three low-temperature H₂O and CO₂ desorption peaks were significantly reduced by employing a soft bake in air at 140° C. for 3 min (FIG. 10). It was concluded that these sub-200° C. peaks represent desorption of molecular and weakly-bound H₂O and CO₂ adsorbents.

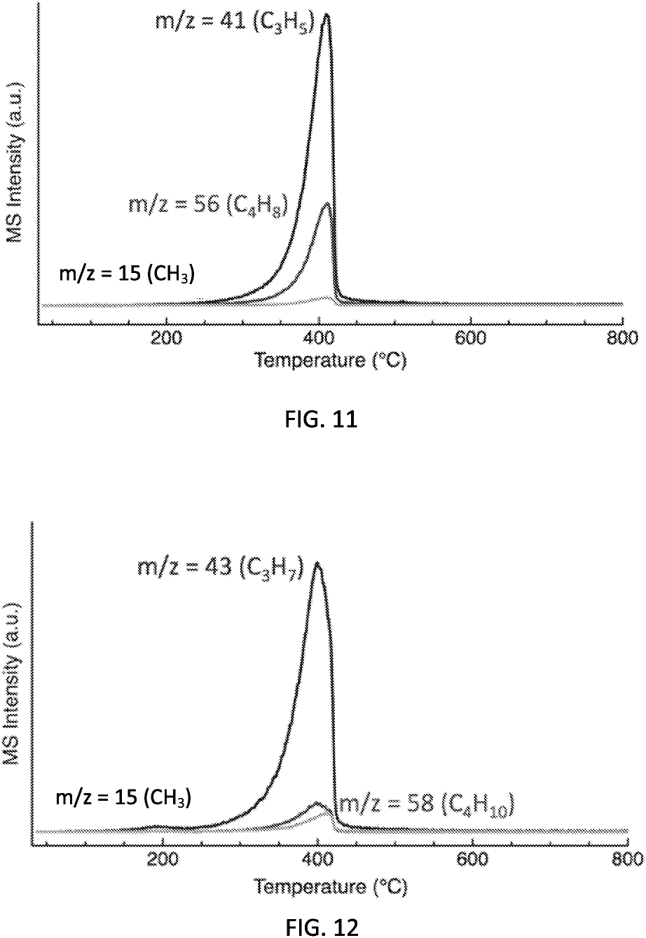

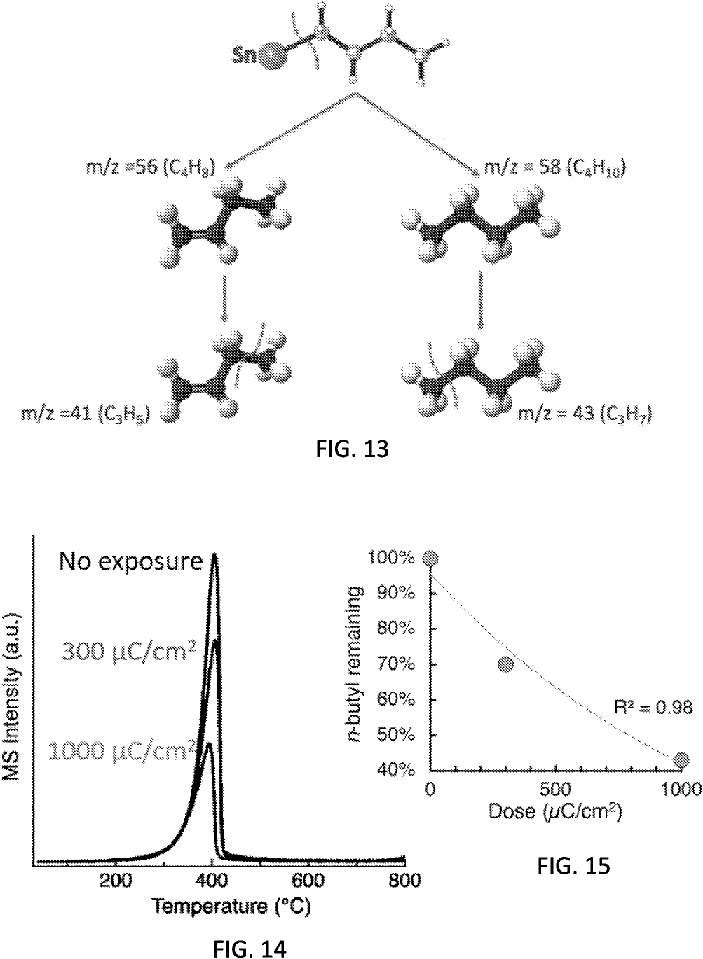

The most intense desorption event from the TPD spectrum of FIG. 8 occurred at 400° C. and uncovered peaks associated with various organic fragments. Thermally induced Sn — C bond scission accompanied by H elimination or abstraction leads to production of 1-butene (C₄H₈) (FIG. 11) or n-butane (C₄H₁₀) (FIG. 12), respectively. The known fragmentation patterns of both products revealed that upon ionization dissociation, propyl fragments were expectedly the most intense signals. FIG. 13 depicts why propyl chains [m/z = 41 (C₃H₅) and m/z = 43 (C₃H₇)] represent 1-butene and n-butane products, respectively.

Because of their similar patterns in the ionizer, establishing the relative amounts of 1-butene (C₄H₈) (FIG. 10) and n-butane (C₄H₁₀) (FIG. 12) is difficult without standardizing the mass spectrometer. However, the expected intensity of m/z = 43 is 100% for n-butane, and essentially 0% for 1-butene. As the experimental spectrum showed a substantial m/z = 43 peak, it is a good indication that Sn — butyl thermolysis of these films resulted in production of both n-butane and 1-butene decomposition products entering the mass spectrometer. Herein after m/z = 41 is used to represent relative butyl concentration in films after various processes, as it was the most intense peak.

At 400° C., m/z = 18 and 44 also peaked. At this temperature, m/z = 44 could be attributed to either CO₂ or C₃H₈, a product fragment of butane. M/z = 18, however, is not a product of C₄H₈ or C₄H₁₀ fragmentation, so it was assigned to water based on the reasoning that the TPD experiment induced Sn — butyl thermolysis with H₂O as a byproduct. Finally, a weak CO₂ peak detected at 600° C. is marked with an asterisk in FIG. 8.

### Exposed Films

1 × 1 cm² films were exposed to electron-beam radiation followed immediately by TPD analysis. This exposure area matched sample dimensions required for TPD analyses. FIG. 14 shows signals associated with n-butyl desorption (m/z = 41) from samples exposed to 0 (black), 300 (blue), and 1000 (red) µC/cm². The intensity of the desorption signal decreased with increasing dose, suggesting that n-butyl content decreased with increasing dose (FIG. 15). The curves of FIG. 14 exhibit three indicators of zeroth-order desorption kinetics: the leading edges are aligned, the trailing edges are separated, and the peak temperature is shifted. Overall, the TPD measurements revealed that electron-beam exposure cleaved Sn — C bonds and induced outgassing of n-butyl ligands, thereby decreasing the concentration of organic ligands in the film.

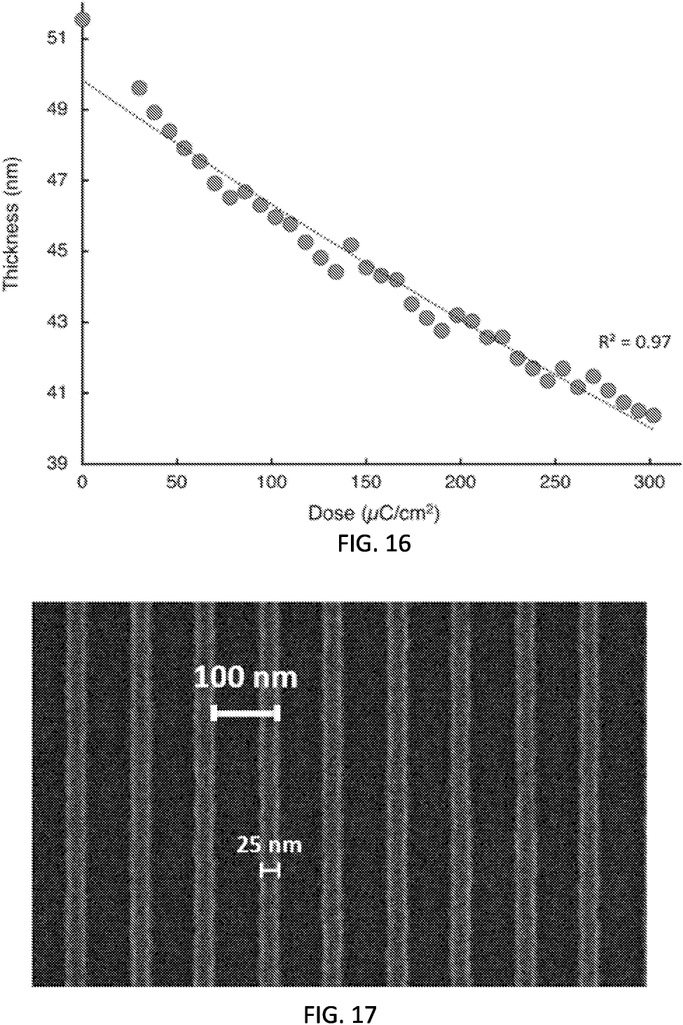

The TPD data in FIG. 14 summarizes the decrease in C₃H₅ signal with increasing exposure dose; the inset shows the signals followed an exponential decay with a fit R² = 0.98. Film thickness from spectroscopic ellipsometry also showed an exponential decrease (FIG. 16) as a function of dose (R² = 0.97). Consequently, these data demonstrate that probability of Sn—C bond scission is simply proportional to the concentration of Sn—C bonds, i.e., butyl groups in the film.

The butyl ligand desorption and change in film thickness and attendant film density indicated that the exposed and unexposed regions of the film could be imaged and characterized by electron microscopy (EM). Narrow lines (~25 nm) were written on a 100-nm pitch in two Sn₁₂OH films with a 30-kV electron beam at a dose of 500 µC/cm². One film was developed in 2-heptanone for 30 s immediately after a 3 minute post-exposure bake (PEB) at 140° C. to confirm via scanning electron microscopy (SEM), which indeed revealed 25-nm lines with 75-nm spacings (FIG. 17).

The second film was not developed. Because the patterned film is extremely sensitive to heat, cryo focused-ion beam milling was employed to extract an electron-transparent lamella for EM analyses. Prior to milling, a layer of chromium was deposited, followed by protective coats of C and Pt, all via vapor methods. Collecting scanning transmission electron microscopy (STEM) images and carbon electron energy loss spectroscopy (EELS) data at cryo temperatures (77 K) prevented additional beam damage.

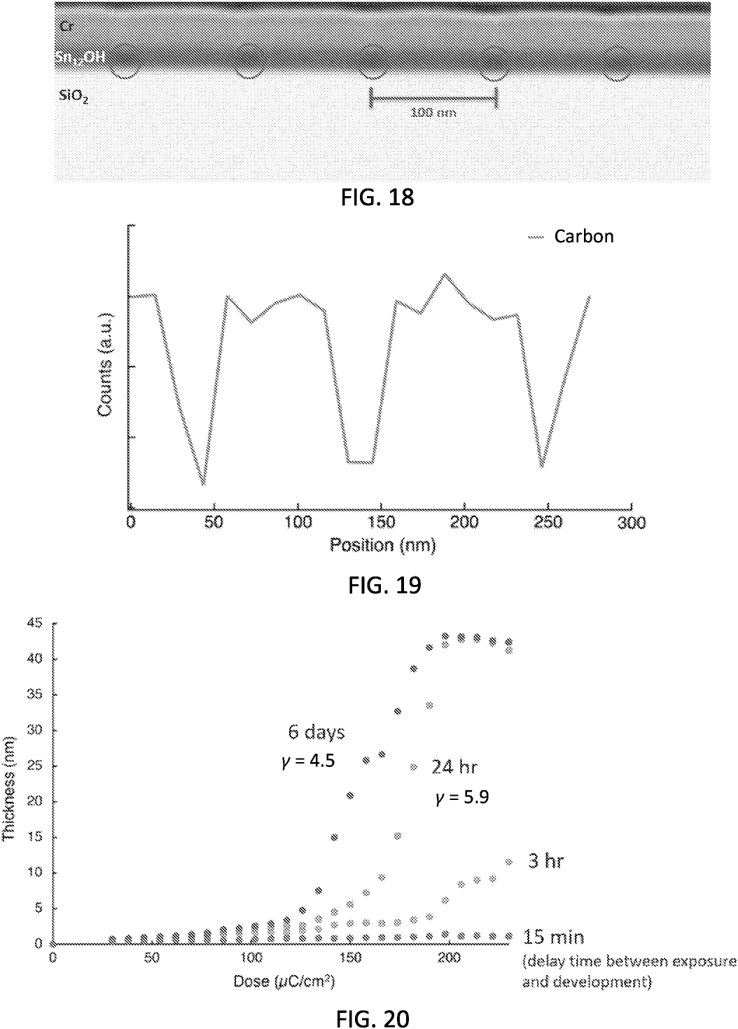

FIG. 18 shows a reverse-contrast, cross-section cryo-STEM image of the exposed, undeveloped sample. From bottom to top, the distinct layers correspond to the SiO₂ substrate (light grey), the exposed Sn₁₂OH (black), and the protective chromium layer (dark grey). The periodic dark regions spaced by ~75 nm represent the exposed regions of the resist. They match the line spacings observed in the fully developed pattern (FIG. 17). Clearly, cryo-STEM coupled with high atomic number contrast enables a unique approach to enable the direct imaging of a normally invisible latent image of an inorganic photoresist.

FIG. 19 shows a line scan of carbon EELS through the exposed Sn₁₂OH film parallel to the substrate, performed at 10 nm resolution. The data showed three distinct dips in the carbon attributable to three exposed areas across the line scan. The lowest carbon counts across each line correspond to a loss of 50 % of the carbon, which equates to 50 % of the butyl ligands. Point scans of carbon EELS produced similar results. These data provide further evidence that irradiation cleaves the Sn — C bond, which leads to desorption of organic species from the film.

Considering the difficulty of the FIB sample preparation and cryoEM measurements, the ~ 50% loss of butyl ligands compares favorably to the ~ 40 % loss observed via TPD. The difference of 10 percentage points may be attributable to the statistical variation in film deposition and processing as well as potential carbon loss during cryo FIB milling and cryo STEM analysis.

### Post-Exposure Delays in Air

Following the procedure detailed in the experimental section, electron-beam exposures were performed in the vacuum chamber of the SEM to produce five controlled-dose arrays. After writing, the samples were removed from the vacuum environment and aged in air prior to 30-s development in 2-heptanone; one array was left undeveloped. FIG. 20 shows film thickness as a function of dose for arrays aged at 0.25, 3, 24, and 144 hours. The undeveloped array serves to identify the delay time required to preserve 100 % of pre-development film thickness.

All the exposed pads on the sample subjected to a 0.25-hr delay simply dissolved in 2-heptanone; no differential dissolution rate was induced between exposed and unexposed regions of the film. After 3 hr in air, a decrease in dissolution rate was observed at highly dosed pads (>200 µC/cm²). After a 24-hr delay, differential dissolution began near 125 µC/cm² and saturated at 200 µC/cm², where the pad thickness equals that of the latent-image control. Continued aging beyond 24 hr resulted in a small shift in sensitivity. The highest measured contrast with 24-hr aging in air was 5.1. Clearly, the delay between exposure and development had a dramatic effect on differential dissolution rates.

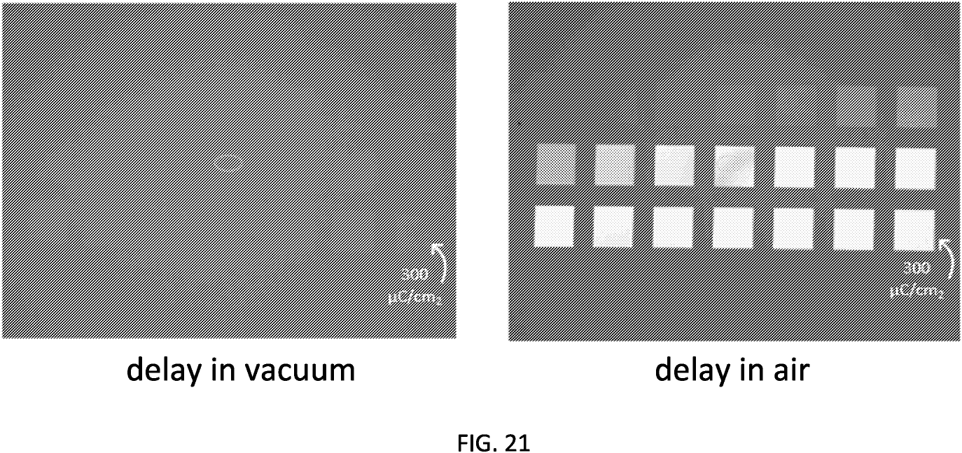

To determine whether aging induces slow changes based on exposure alone or reactions with air, an array aged in vacuum was compared directly with one aged in air, each for two hrs. FIG. 21 shows that only the air-delayed sample yielded a distinct contrast between exposed and unexposed regions upon development in acetone. With these observations, it was concluded that absorption of one or more air constituents [CO₂(g), H₂O(g), O₂(g)] is required to alter the dissolution rate. Note, the arrays of FIG. 21 were the only arrays developed in acetone. Acetone was used as the developer in this experiment as shorter delay-times (> 24 hr) are required to observe a switch in solubility. 2-heptanone was used for all other development steps reported, as it yields higher contrast.

Two 1 × 1 cm² samples were exposed to 1000 µC/cm² of electron-beam radiation. After exposure, one sample was immediately transferred to the ultrahigh vacuum (UHV) chamber of the TPD instrument, while the other sample was aged for 10 days in air. The transfer from the SEM to the TPD took ~ 15 min. An arbitrarily high exposure dose coupled with a long delay time in air was selected to maximize reaction products on films, and thereby desorption signals in the TPD-MS.

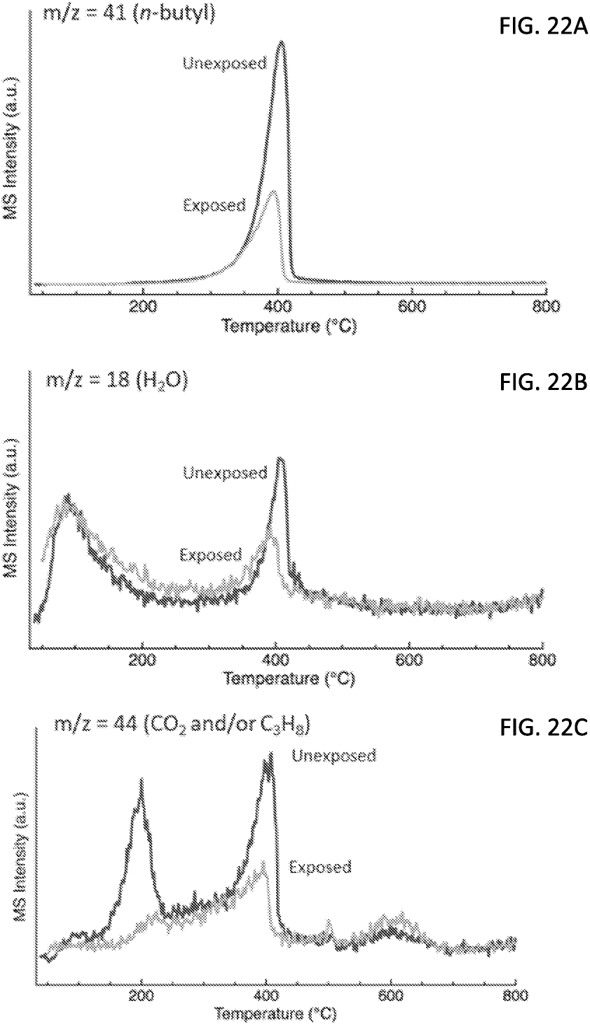

FIGS. 22A-22C show n-butyl, H₂O, and CO₂ desorption signals, respectively, for an unexposed film and from an exposed and immediately-transferred sample. All three species show an overall decrease in desorption after exposure at 1000 µC/cm².

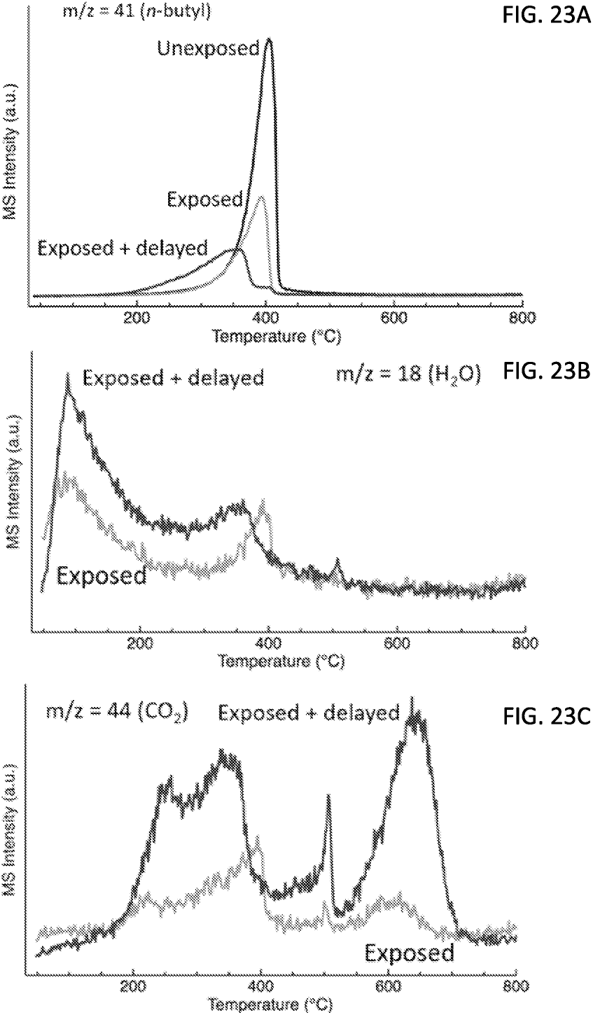

FIGS. 23A-23C show the H₂O (23A), CO₂ (23B), and n-butyl (23C) desorption curves from the immediate versus air-aged samples, each exposed to 1000 µC/cm². FIG. 23A reveals that a 10-day delay in air resulted in higher-intensity H₂O desorption. The low-temperature signal for desorption of constitutional water (FIG. 9A) shifted from 75 to 90° C. due to increased H₂O concentration on the film. A higher signal for desorption of constitutional H₂O was anticipated these films were shown to adsorb H₂O from air (FIG. 9A). The strong H₂O desorption represented by the line between 200 and 300° C. indicates the aged film was more extensively hydroxylated than the unaged film. Consequently, the hydrophilic, aged film absorbed more water, which is evident by the higher H₂O desorption signal between 75 and 150° C. in the aged film.

FIG. 23B discerns CO₂ signals for the same two samples. Significantly higher CO₂ desorption signals were observed from an exposed sample aged in air for 10 days compared with an unaged film. The area under the exposed curve is ~ 4X that of the unaged curve. These signals are associated with HCO₃⁻ and CO₃²⁻ rather than weakly-bound CO₂ adsorbents (FIG. 9B), as the signals of FIG. 23B only desorbed at temperatures above 200° C.

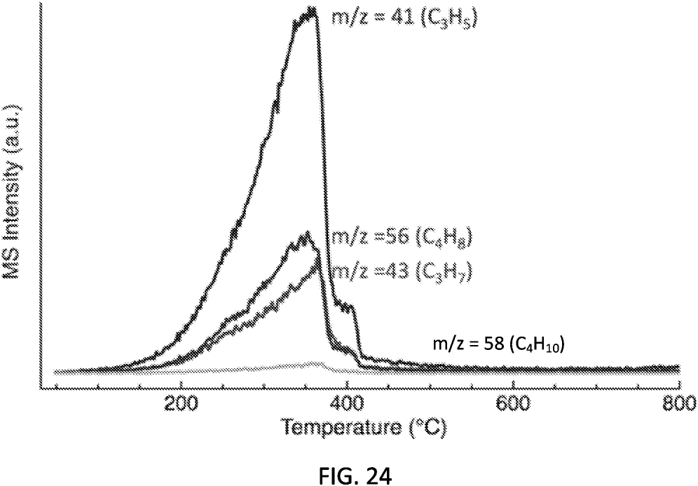

Finally, the exposed curve of FIG. 23C shows that the 10-day delay in air shifted the onset for butyl desorption from 300 to 175° C. and the peak signal from 400 to 350° C.; the same trend was observed for the other organic fragments of m/z = 43 (C₃H₇), 56 (C₄H₈), and 58 (C₄H₁₀) (FIG. 24). The areas under the curves of FIG. 23C agree within 5 % of one to the other, indicating essentially no change in the concentration of the ligands remaining after aging. These spectra reveal that outgassing of organics is limited only to the exposure process, and that the chemical environment of the remaining butyl ligands changed after aging in air. The shift in peak signals for both n-butyl desorption and the high-temperature H₂O desorption from 400 to 350° C. (FIG. 23A) continues to support that the high-temperature water desorption is a byproduct associated with n-butyl decomposition.

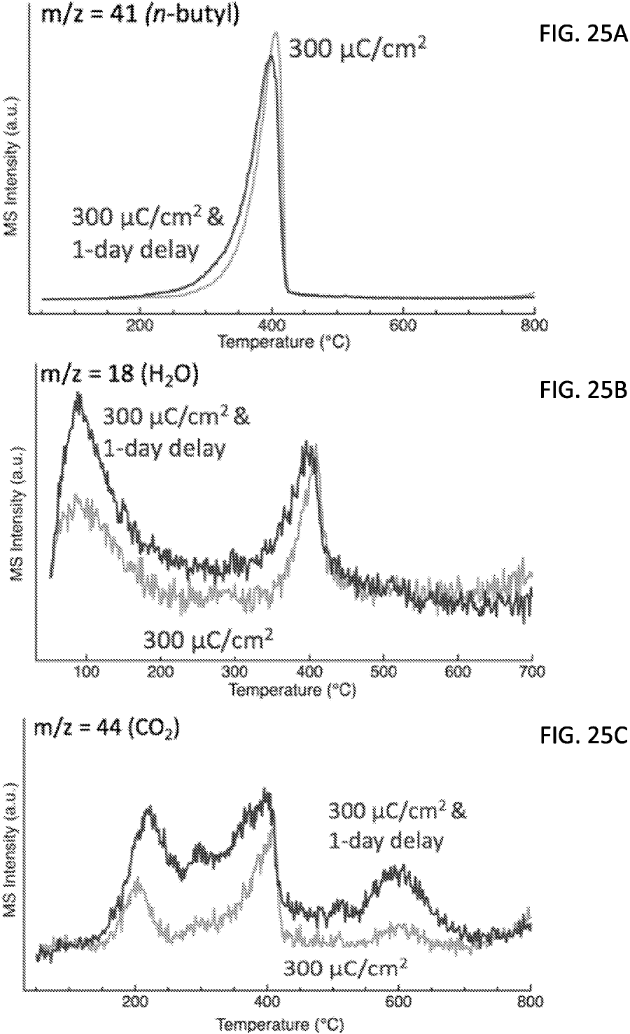

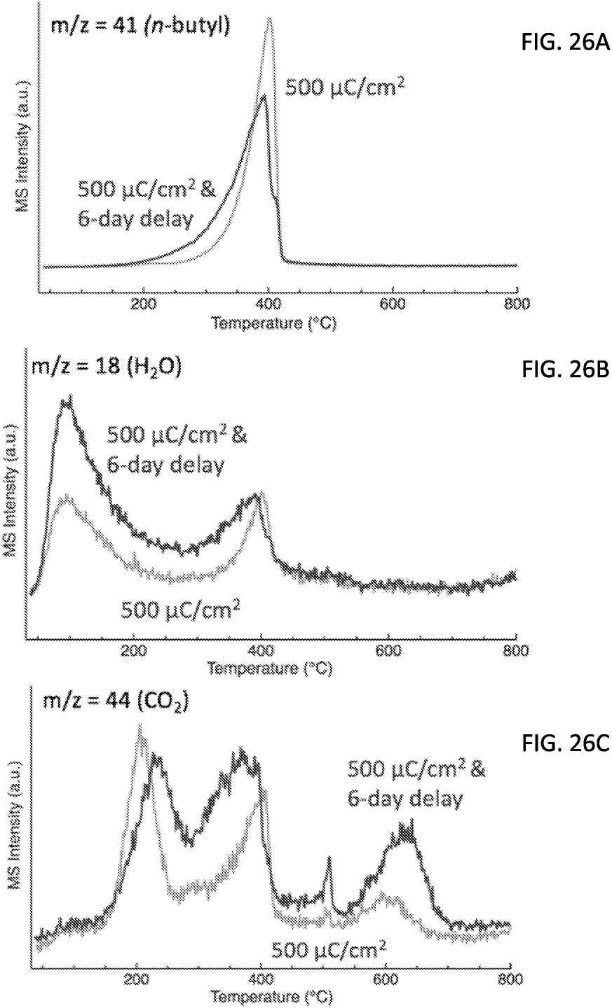

Although weaker intensities were observed, the same trends followed upon exposure to 300 and 500 µC/cm² and 1-day or 6-day delays in air (FIGS. 25A-25C, 26A-26C).

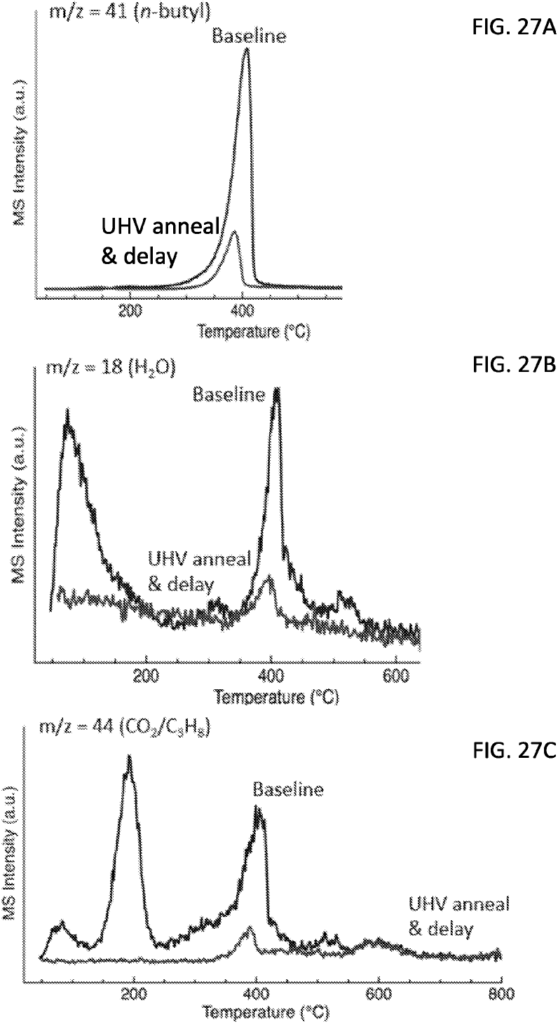

FIGS. 27A-27C show that n-butyl groups may be eliminated by heating Sn₁₂ films in air (27A). These n-butyl deficient films then absorb H₂O (27B) and CO₂ (27C) in a manner similar to the electron-beam exposed films to produce hydroxides, bicarbonates, and carbonates.

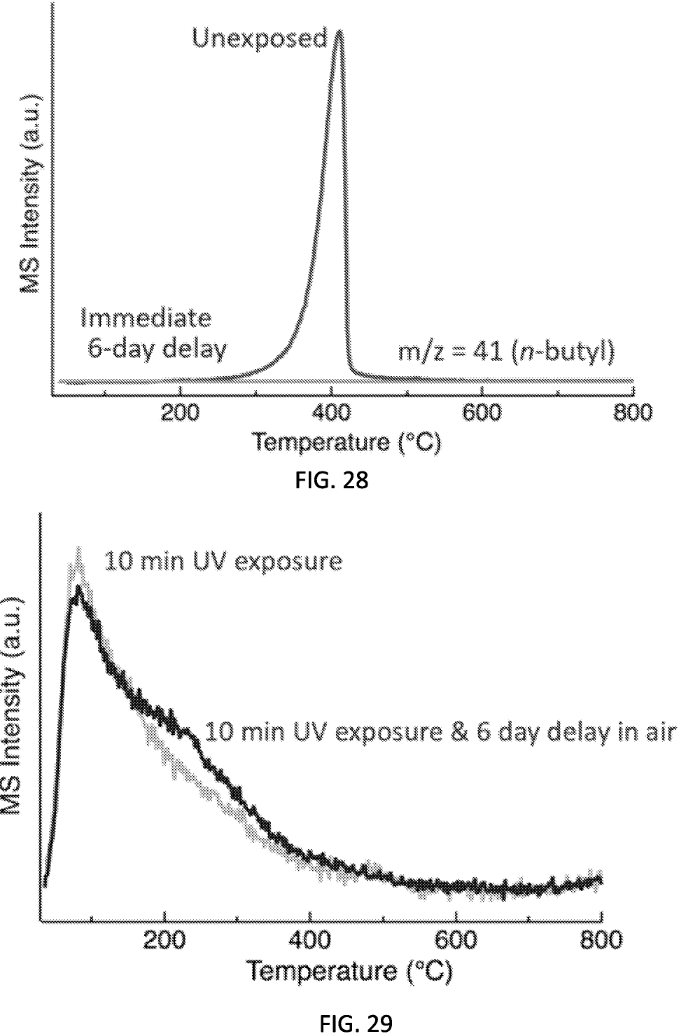

The TPD experiments were repeated on immediate- and air-delayed samples exposed to ultraviolet (UV) light (λ, = 254 nm). The samples were exposed for 10 min; one sample was immediately brought into the UHV TPD chamber, while the other was aged for 6 days in air. FIG. 28 shows the butyl desorption from the exposed sample compared with the signal from an unexposed sample. The data show a complete elimination of the m/z = 41 peak, which means that the exposure dose was sufficient to cleave all the Sn — C bonds and evolve the ligand products. None of the other butyl-related desorption masses were detected, supporting complete elimination rather than decomposed fragments trapped in the film.

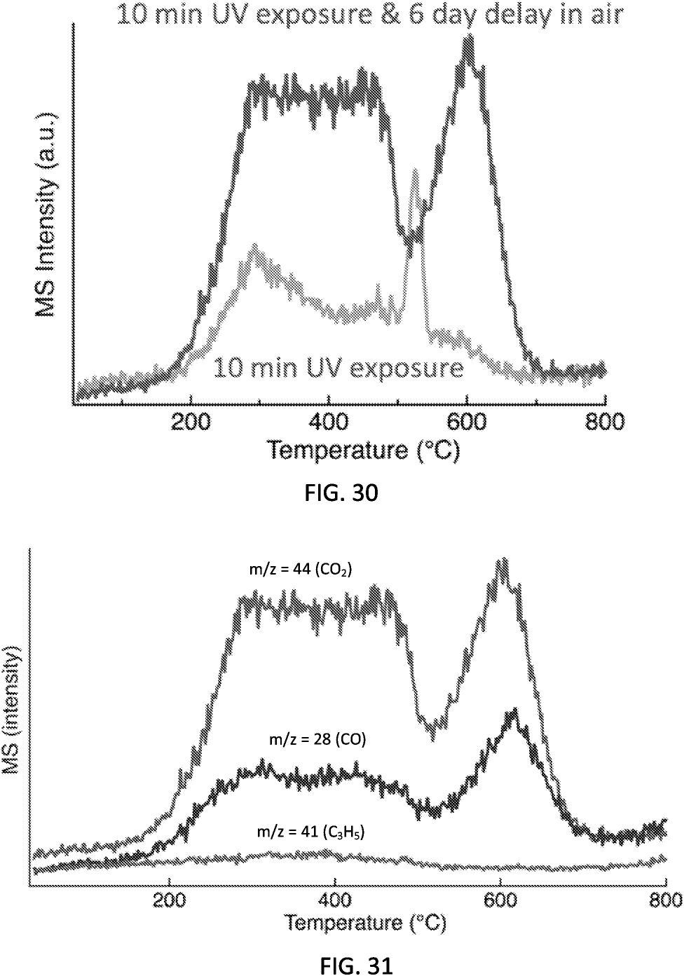

FIG. 29 shows negligible differences in the H₂O desorption spectra from the unaged and aged samples. The CO₂ desorption is shown in FIG. 30; again, significantly higher desorption signals are observed after aging in air. The identical peak-shape of m/z = 44 (CO₂⁺) and 28 (CO⁺) provides more confidence that m/z = 44 is indeed representative of CO₂ (FIG. 31).

It has been shown that carbon dioxide inserts smoothly into the Sn — O bond of tin alkoxides, and into the Sn — O bond of tin hydroxides on metal-oxide surfaces. Numerous reports have described incorporation of carbonate into SnₓO_{y} cores, even stating that di-n-butyltin oxide, for example, is an efficient CO₂ capture agent.

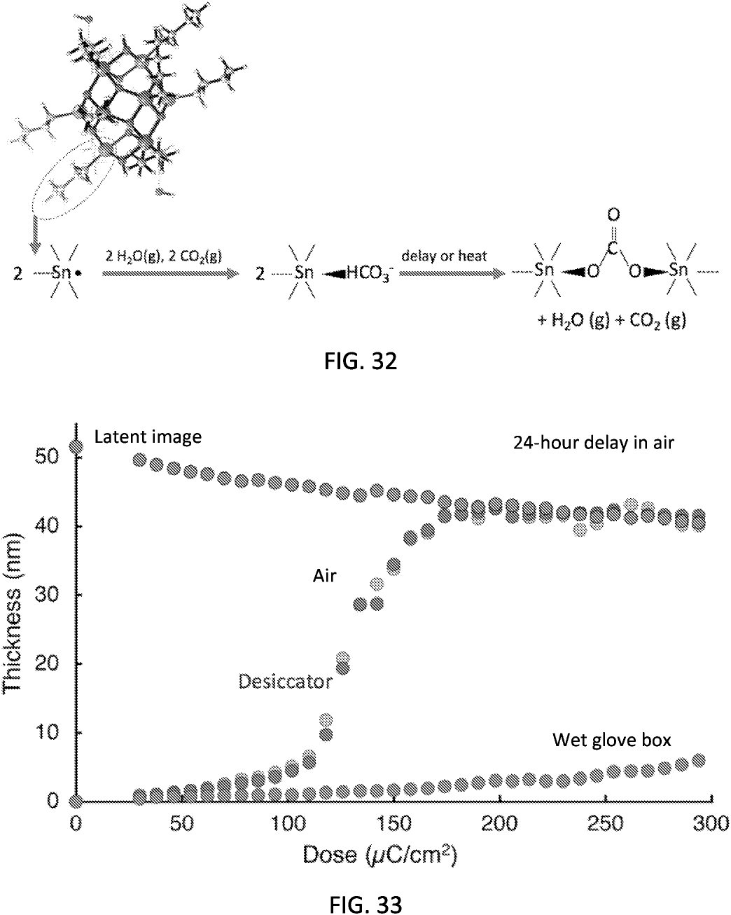

Without wishing to be bound by a particular theory of operation, the chemical reactions in FIG. 32 contribute to differential dissolution of n-butyltin oxide hydroxide. Electron-beam or UV exposure cleaves the Sn — C bond, promoting desorption of the butyl ligand as butane or butene. Once samples are introduced to atmosphere, the Sn sites of exposed areas hydrolyze, thereby increasing the concentration of Sn — OH^{—}. Over time the films absorb CO₂, which inserts into the Sn — OH bond to form bicarbonate. Adjacent bicarbonates may then react and release H₂O to form simple carbonates. Formation of Sn carbonates could inhibit solubility by condensation via CO₃²⁻ bridges. Formation of terminal bicarbonate ligands HCO₃⁻ bound to Sn could also influence solubility via its significant polarity difference relative to the n-butyl ligand. Either carbonate species could yield a differential dissolution contrast.

It was ascertained that the gradual alteration in dissolution rate (FIG. 20) was a direct result of the gradual CO₂ adsorption, and thus gradual bicarbonate and carbonate formation. It was hypothesized that formation of carbonate species weakens the Sn — C bond, as a decrease in the n-butyl decomposition temperature was observed (FIG. 23C).

FIG. 33 demonstrates that both H₂O and CO₂ are required to realize dissolution contrast in an Sn₁₂ film exposed to an electron beam. Three different dose arrays were exposed with 24-hour delays in air (baseline), a desiccator (H₂O-deficient environment), and a wet glove box (CO₂-deficient environment), and then developed for 30 s in 2-heptanone. The film exposed to radiation showed no dissolution contrast when aged in a humid environment without CO₂ (a wet glove box).

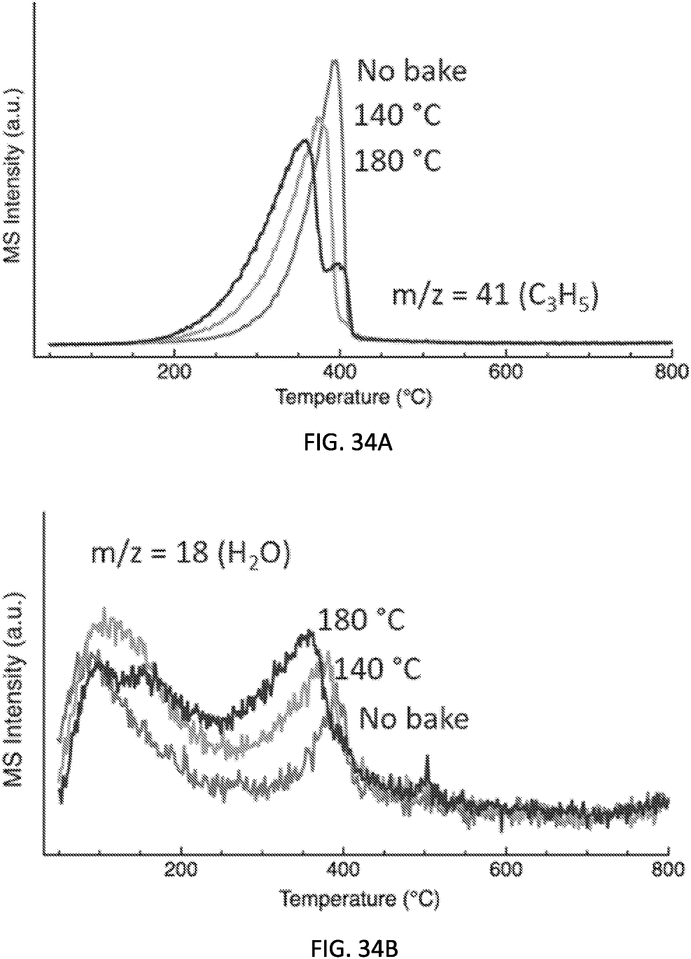

M/z = 32, corresponding to O₂, was never detected above baseline in any of the TPD experiments. Additionally, when a dose array was delayed for 24 hours in an isolated O₂(g) environment, no pattern was observed upon development (FIGS. 34A-34B tracking n-butyl (34A) and water (34B) desorption). These data suggest that, at least alone, O₂(g) will not complete the radiation-induced reactions, thus its involvement was excluded.

### Post-Exposure Bakes

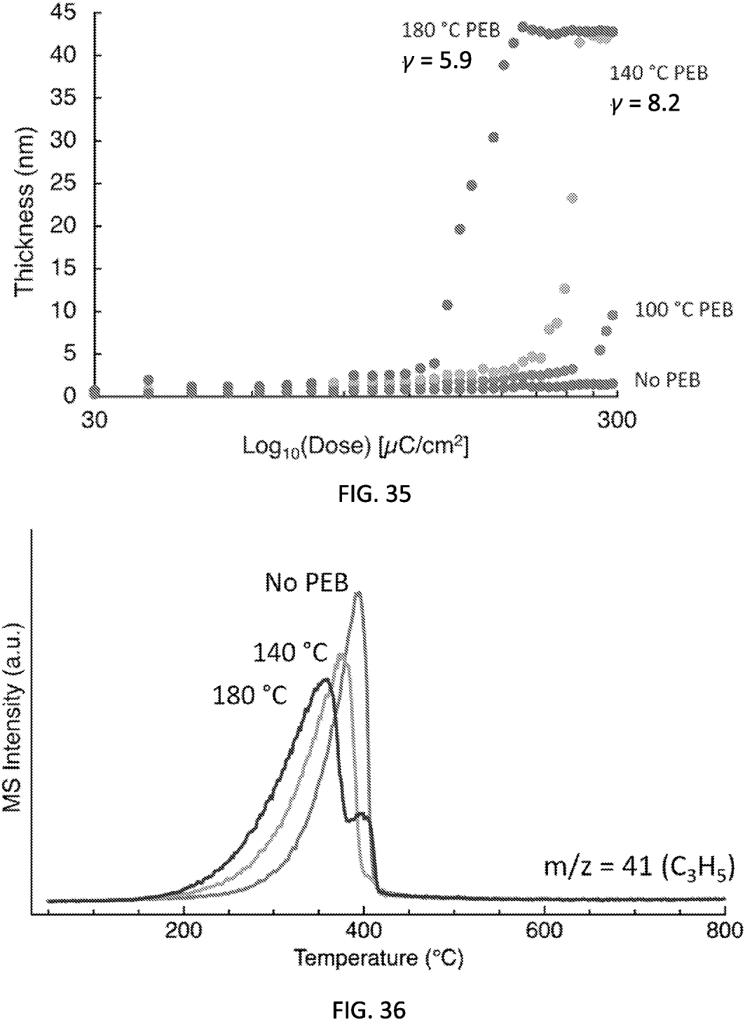

FIG. 35 shows thickness measurements for dose arrays subjected to no PEB, 100° C. PEB, 140° C. PEB, and 180° C. PEB for 3 min. All of the samples were then immediately developed in 2-heptanone for 30 s, such that there is no additional delay time apart from the 3 min PEB.

The unbaked dose array revealed no dissolution contrast upon removal from vacuum and immediate development. The sample baked at 100° C. yielded a reduced dissolution rate at doses near 300 µC/cm². After 140 and 180° C., the pads exhibited pre-development thickness by 260 and 200 µC/cm², respectively. These data show that employing a PEB at T ≥ 140° C. provides sufficient energy to produce insoluble products at exposure doses below 300 µC/cm², and bypasses the delay time. FIG. 36 shows that heating induced the n-butyl groups to desorb from the Sn₁₂ film at lower temperatures.

Electron-beam exposures followed by TPD were repeated, this time adding a PEB step to the large 1 × 1 cm² exposed areas. Three samples were exposed at 1000 µC/cm² and only two of them were subjected to 3-min PEBs at 140° C. and 180° C. immediately after exposure. They were then placed rapidly into the UHV chamber of the TPD to minimize exposure to air. The desorption spectra after PEB were observed to be largely the same as the spectra after prolonged delays in air.

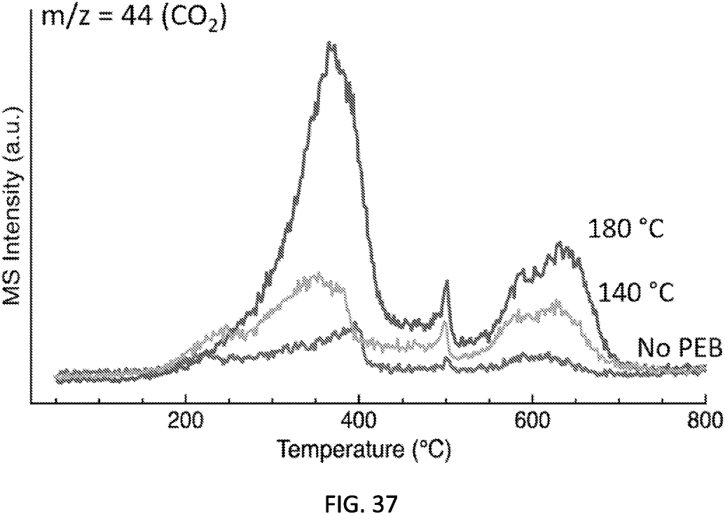

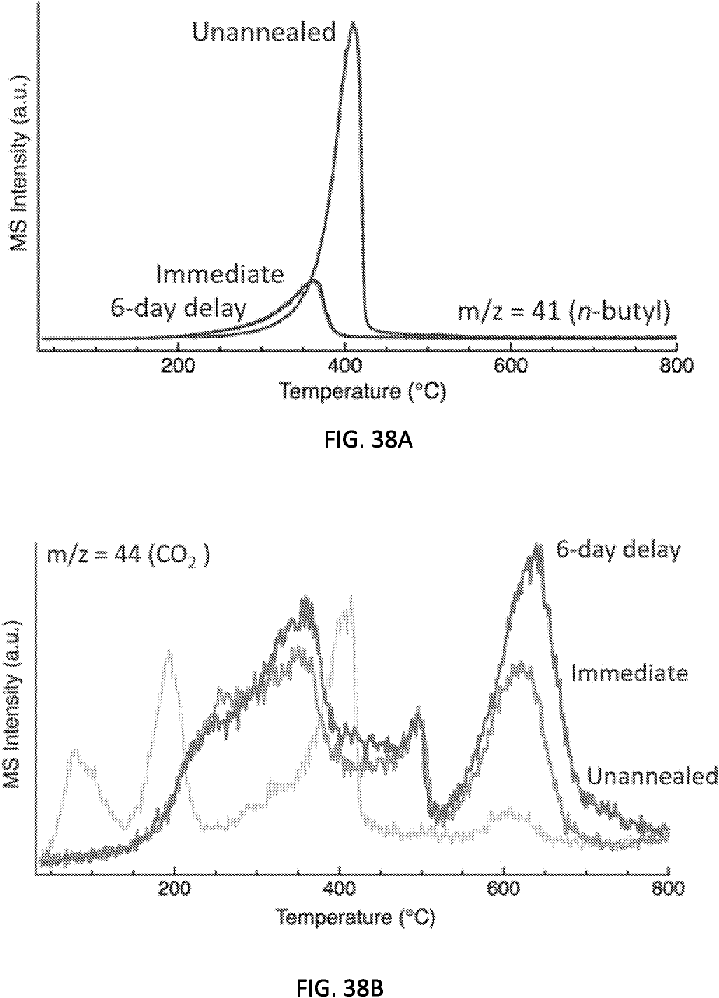

FIG. 37 shows the CO₂ desorption from the three samples; the signals increased significantly with an increase of PEB temperatures, suggesting increasing concentrations of carbonate species. We also show that with increasing PEB temperatures, the n-butyl desorption shifts to lower peak temperatures, and H₂O desorption increases (FIG. 34A, FIGS. 38A, 38B). After a 3 min PEB at 320° C., 80% of butyl ligands were lost. Both of these trends are consistent with the results for samples aged in air for prolonged periods at room temperature.

FIGS. 35 and 37 suggest that exposed samples will not yield differential dissolution if developed immediately after exposure in vacuum, as the carbonate concentration is relatively low. Dissolution is efficiently inhibited, however, when higher concentrations of carbonate species are observed. It was concluded that PEB processes simply provide sufficient energy to activate the CO₂(g) reaction with hydrolyzed Sn, speeding the reaction rate.

An assessment was performed to determine whether the —OH^{—} bound to Sn is the active site for carbonate formation. To do this, both unexposed and exposed samples were baked in air up to 180° C. and their desorption spectra were compared before and after heating. Baking an unexposed sample essentially translates to baking fully intact Sn₁₂OH species. Baking an exposed sample represents baking butyl-deficient Sn atoms that have hydrolyzed upon introduction to atmosphere.

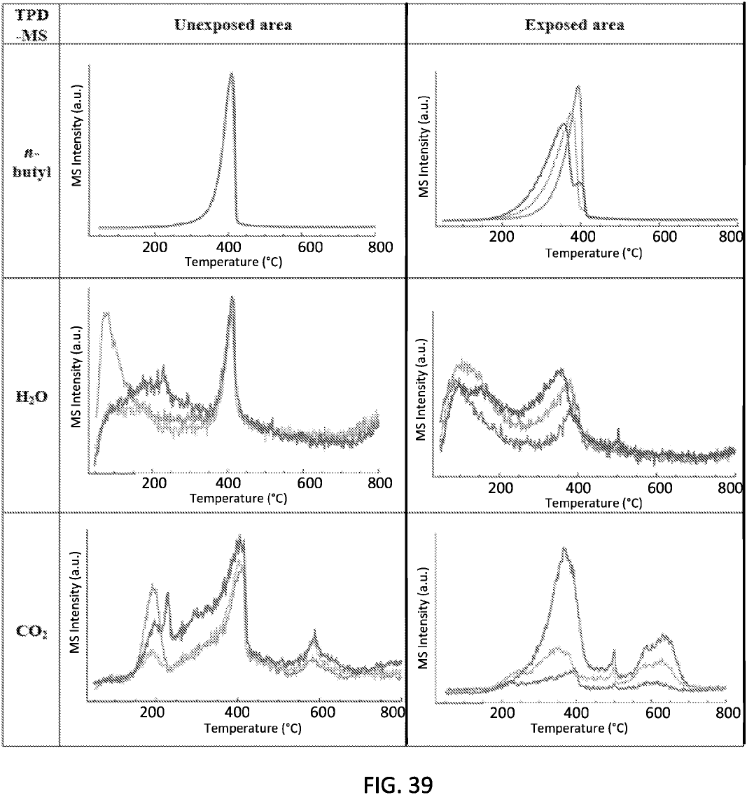

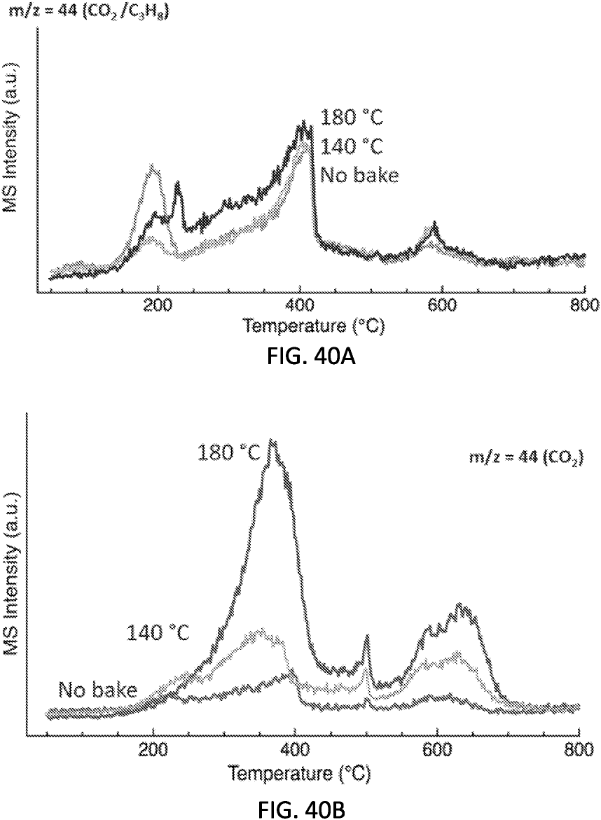

FIGS. 39 and 40A-40B show that the desorption spectra of all three species (n-butyl, H₂O, CO₂) changed dramatically upon baking in air only in exposed samples. As previously mentioned, exposed films baked at 180° C. showed an increase of CO₂ desorption, suggesting an increase of carbonate groups in films. When baking unexposed samples, the desorption spectra before and after heating were largely unchanged. As such, it was concluded that Sn—OH^{—} sites absorb CO₂(g) to form bicarbonate and carbonate.

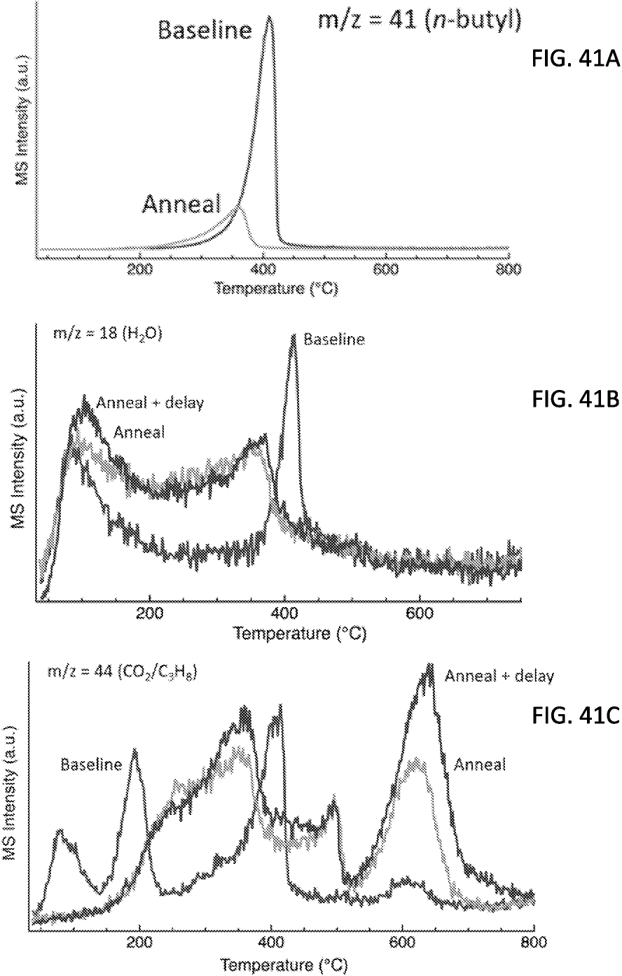

It was hypothesized that both HCO₃^{—} and CO₃^{2—} form in films during aging in air or baking at temperatures up to 180° C. (FIGS. 23B, 37, and 41A-41C). The CO₂ peaks in the TPD spectra between 200 - 400° C. were attributed to decomposition of Sn bicarbonate as H₂O signals were also observed in that temperature range. Above 400° C., CO₂ peaks likely represent decomposition of Sn carbonate, as H₂O peaks were undetected.

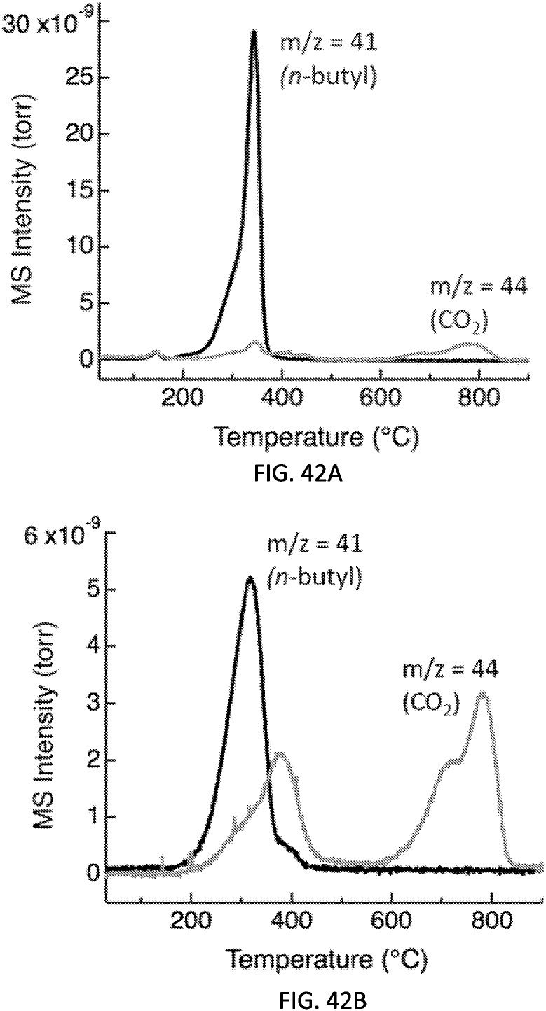

Thermogravimetric analysis-mass spectrometry was performed to mimic partial exposure on bulk Sn₁₂OH powders. TGA-MS was performed on Sn₁₂OH in N₂ to establish a baseline (FIG. 42A) and Sn₁₂OH baked in air to decompose some of the butyl ligands, thereby mimicking exposure (FIG. 42B). The same trends were observed in the bulk powders.

### Patternability - Proof of Concept

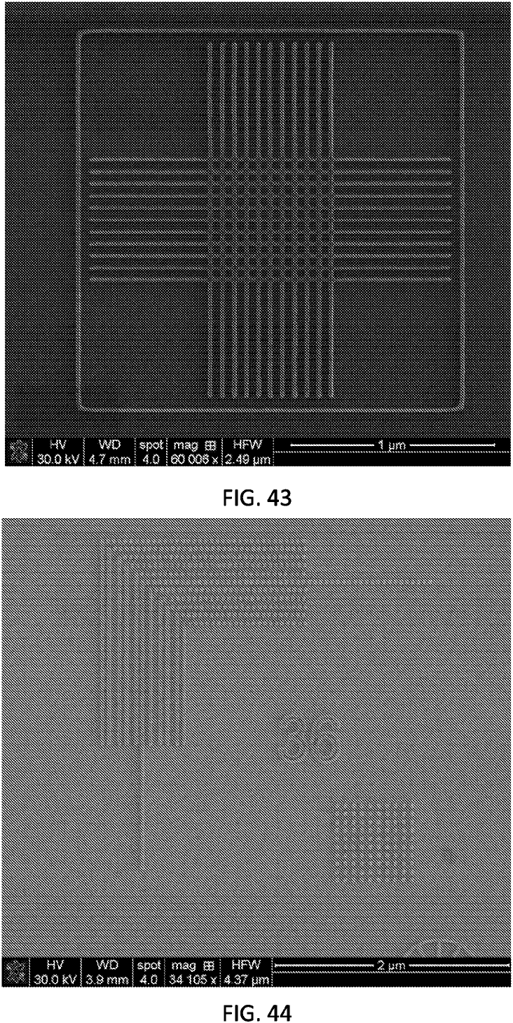

Based on all previous observations, Sn₁₂OH was lithographically patterned at 400 µC/cm², PEB at 140° C., and 30 s development in 2-heptanone. FIG. 43 is an SEM image of 10-nm lines on a 60-nm pitch in the horizontal direction and 14-nm lines on a 60-nm pitch in the vertical direction. The difference in linewidth between the horizontal and vertical line resulted from differences in beam step size in the two directions. FIG. 44 is an SEM image of line and space patterns and dot patterns produced by the process: Sn₂ deposition, conversion to Sn₁₂OH via an NH₃(aq) soak, electron-beam exposure, post-exposure bake at 180° C., and development in 2-heptanone.

### Conclusions

A method to produce Cl-free, atomically smooth Sn₁₂OH films was developed, representing a model system to elucidate chemical processes contributing to its high-resolution patterning capabilities. TPD-MS was used to analyze the chemical changes of films after exposure to radiation, aging in air, and baking. CryoSTEM and cryoEELS measurements confirmed the TPD results. The spectra showed that radiation cleaves the Sn — C bond, inducing the desorption of butane and butene. Once introduced to atmosphere, exposed films absorb H₂O(g) and CO₂(g) to form hydroxide, bicarbonate, and carbonate. In aged films at room temperature, limited evidencewas found for extensive condensation. Here, the exchange of n-butyl ligands for OH⁻, HCO₃⁻, and CO₃²⁻ alone may be sufficient to induce a dissolution rate contrast between exposed and unexposed regions of the film. Post-exposure baking accelerates H₂O(g) and CO₂(g) absorption and produces dissolution contrast similar to that of aging. The amount of additional cross linking that may occur with baking requires additional study.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. A composition, comprising R_{q}SnOₘ(OH)ₓ(HCO₃)_{y}(CO₃)_{z} where:
R is (i) C₁—C₁₀ hydrocarbyl or (ii) heteroaliphatic, heteroaryl, or heteroaryl-aliphatic including 1-10 carbon atoms and one or more heteroatoms;
$$q = \text{0} \text{.1-1} ;$$
$$x \leq 4 ;$$
$$y \leq 4 ;$$
$$z \leq 2 ;$$
$$m = 2 - q \text{/2} - x \text{/2} - y \text{/2} - z ; \text{and}$$
$$\left(q / 2 + x / 2 + y / 2 + z\right) \leq 2$$
.

2. The composition of claim 1 where R is C₁—C₁₀ aliphatic.

3. The composition of claim 1 where R is C₁—C₅ alkyl.

4. The composition of claim 1 where R is n-butyl.

5. The composition of any one of claims 1-4 where:
$$q = 0.1 - 1 ;$$
$$x \leq 3.9 ;$$
$$y \leq 3.9 ; \text{and}$$
$$z \leq 1.95$$
.

6. The composition of any one of claims 1-5 where:
(i) 0 < x ≤ 3; or
(ii) 0 <y ≤ 3; or
(iii) 0 < z ≤ 1.5; or
(iv) any combination of (i), (ii), and (iii).

7. A composition, comprising R_{q}SnOₘ(OH)ₓ(HCO₃)_{y}(CO₃)_{z} where:
R is (i) C₁—C₁₀ hydrocarbyl or (ii) heteroaliphatic, heteroaryl, or heteroaryl-aliphatic including 1-10 carbon atoms and one or more heteroatoms;
$$q = 0.1 - 1 ;$$
$$x \leq 3.9 ;$$
$$y \leq 3.9 ;$$
$$z \leq 1.95 ;$$
$$m = 2 - q / 2 - x / 2 - y / 2 - z ; \text{and}$$
$$\left(q / 2 + x / 2 + y / 2 + z\right) \leq 2$$
.

8. A component, comprising:
a substrate; and
a film on at least a portion of the substrate, the film comprising the composition of any one of claims 1-7.

9. The component of claim 8, wherein the film is patterned on the substrate.

10. The component of claim 8 or claim 9, wherein:
(i) the film has an average thickness within a range of 2-1000 nm; or
(ii) the film has a root-mean-square surface roughness < 1.5 nm; or
(iii) both (i) and (ii).

11. A method, comprising:
exposing RSnX₃ to air, thereby producing [RSnOH(H₂O)X₂]₂, where X is halo and R is (i) C₁—C₁₀ hydrocarbyl or (ii) heteroaliphatic, heteroaryl, or heteroaryl-aliphatic including 1-10 carbon atoms and one or more heteroatoms;
preparing a solution comprising the [RSnOH(H₂O)X₂]₂ and a solvent;
depositing the solution onto a substrate;
heating the deposited solution and the substrate to produce a film comprising [(RSn)₁₂O₁₄(OH)₆]X₂ on the substrate; and
contacting the film comprising [(RSn)₁₂O₁₄(OH)₆]X₂ with aqueous ammonia to produce a film comprising [(RSn)₁₂O₁₄(OH)₆](OH)₂ on the substrate.

12. The method of claim 11 where R is C₁—C₁₀ aliphatic.

13. The method of claim 11 where R is C₁—C₅ alkyl.

14. The method of claim 11 where R is n-butyl.

15. The method of any one of claims 11-14, where heating the deposited solution and the substrate to produce a film comprising [(RSn)₁₂O₁₄(OH)₆]X₂ on the substrate comprises heating at a temperature within a range of 60-100° C. for 1-5 minutes.

16. The method of any one of claims 11-15, further comprising irradiating at least a portion of the film comprising [(RSn)₁₂O₁₄(OH)₆](OH)₂ with an electron beam or light having a wavelength within a range of from 10 nm to less than 400 nm to produce an irradiated film.

17. The method of claim 16, wherein irradiating comprises:
irradiating with light having a wavelength within a range of 10-260 nm; or
irradiating with an electron beam at a dose of ≥ 125 µC/cm².

18. The method of claim 17, wherein irradiating comprises irradiating with an electron beam at a dose of 125-1000 µC/cm².

19. The method of any one of claims 16-18, wherein irradiating cleaves from 10-100% of R—Sn bonds in irradiated portions of the film comprising [(RSn)₁₂O₁₄(OH)₆](OH)₂.

20. The method of any one of claims 16-19, further comprising:
(i) exposing the irradiated film to air at ambient temperature for at least 3 hours; or
(ii) heating the irradiated film at a temperature within a range of 100-200° C. in air for 2-5 minutes,
whereby irradiated portions of the irradiated film adsorb CO₂ from the air, forming R_{q}SnOₘ(OH)ₓ(HCO₃)_{y}(CO₃)_{z}, wherein q = 0.1-1, x ≤ 4, y ≤ 4, z ≤ 2, m = 2 - q/2 - x/2 - y/2 - z, and (q/2 + x/2 + y/2 + z) ≤ 2.

21. The method of claim 20, wherein q = 0.1-1, x ≤ 3.9, y ≤ 3.9 and, z ≤ 1.95.

22. The method of claim 20 or 21, wherein:
(i) the irradiated film is exposed to air at ambient temperature for 1-10 days; or
(ii) the irradiated film is heated at a temperature within a range of 140-180° C. for 3 minutes.

23. The method of any one of claims 16-22, wherein portions of the film comprising [(RSn)₁₂O₁₄(OH)₆](OH)₂ are irradiated to form a patterned film, the method further comprising:
contacting the patterned film with a solvent in which [(RSn)₁₂O₁₄(OH)₆](OH)₂ is soluble and irradiated portions of the film are less soluble for a period of time effective to dissolve [(RSn)₁₂O₁₄(OH)₆](OH)₂ without dissolving irradiated portions of the patterned film.

24. A component made by the process of claim 11, the component comprising:
a substrate: and
a film on at least a portion of the substrate, the film comprising [(RSn)₁₂O₁₄(OH)₆](OH)₂, wherein
(i) the film has a root-mean-square surface roughness of ≤ 0.8 nm, or
(ii) the film has an undetectable level of Cl⁻ as determined by X-ray photoelectron spectroscopy, or
(iii) both (i) and (ii).

25. The film of claim 24, wherein the root-mean-square surface roughness is ≤ 0.5 nm.

26. A component made by the process of any one of claims 20-23, the component comprising:
a substrate; and
a film on at least a portion of the substrate, the film comprising R_{q}SnOₘ(OH)ₓ(HCO₃)_{y}(CO₃)_{z}, wherein q = 0.1-1, x ≤ 4, y ≤ 4, z ≤ 2, m = 2 - q/2 - x/2 - y/2 - z, and (q/2 + x/2 + y/2 + z) ≤ 2.

27. The component of claim 26, wherein q = 0.1-1, x ≤ 3.9, y ≤ 3.9 and, z ≤ 1.95.
